(19) United States
(12) Patent Application Publication
(10) Pub. No.: US 2019/0267551 A1
(43) Pub. Date: Aug. 29, 2019

(54) NANOPARTICLE-CONDUCTING POLYMER COMPOSITE FOR USE IN ORGANIC ELECTRONICS

(71) Applicant: NISSAN CHEMICAL INDUSTRIES, LTD., TOKYO (JP)

(72) Inventors: Mark SIMS, Pittsburgh, PA (US); Sergey B. LI, Glenshaw, PA (US); Olivier GAUDIN, Pittsburgh, PA (US); Michael PANNONE, Indianola, PA (US); Elena SHEINA, Pittsburgh, PA (US)

(21) Appl. No.: 16/065,689

(22) PCT Filed: Dec. 28, 2016
(86) PCT No.: PCT/JP2016/005258

§ 371 Date: Jun. 22, 2018

Related U.S. Application Data
(60) Provisional application No. 62/271,743, filed on Dec. 28, 2015.

(51) Int. Cl. H01L 51/00; H01L 51/42; C09D 11/102; C09D 11/52; C09D 11/03

(52) U.S. Cl. CPC H01L 51/0036; H01L 51/426; C09D 11/102; H01L 51/5088; C09D 11/03; H01L 2251/5369; C09D 11/52

(57) ABSTRACT

Described herein are nanoparticle-conductive polymer composite films containing a polythiophene having a repeating unit complying with formula (I) described herein and one or more metallic or metalloid nanoparticles and their use, for example, in organic electronic devices. The present disclosure also concerns the use of one or more metallic or metalloid nanoparticles in organic electronic devices to improve light outcoupling leading to increased efficiency, to improve color saturation, and to improve color stability.

### TECHNICAL FIELD

The present disclosure relates to nanoparticle-conducting polymer composite films and uses thereof, for example, in organic electronic devices.

### BACKGROUND ART

Although useful advances are being made in energy saving devices such as, for example, organic-based organic light emitting diodes (OLEDs), polymer light emitting diodes (PLEDs), phosphorescent organic light emitting diodes (PHOLEDs), and organic photovoltaic devices (OPVs), further improvements are still needed in providing better materials processing and/or device performance for commercialization. For example, in state-of-the-art OLED devices, the internal quantum efficiency is near 100% using various materials, such as electro-phosphorescent and thermally activated delayed fluorescence (TADF) materials. However, the external quantum efficiency of OLED devices without light out-coupling remains near 20% because of losses due to wave-guiding effects.

High efficiency OLEDs usually comprise a multiplicity of different layers, each layer being optimized towards achieving the optimum efficiency of the overall device. Typically, such OLEDs comprise a multilayer structure comprising multiple layers serving different purposes. The typical OLED device stack comprises an anode, a hole transport layer (HTL), an emissive layer (EML), an electron transport layer (ETL), and a cathode. Optionally, a hole injection layer (HIL) may be disposed between the anode and HTL, or an electron injection layer (EIL) may be disposed between cathode and the ETL).

OLED emissive materials generally have a refractive index greater than 1.7, which is substantially higher than that of most of the supporting substrates, which are usually around 1.5. As light propagates from a higher index medium to a lower index medium, total internal reflection (TIR) occurs for light beams travelling in large oblique angles relative to the interface, according to Snell's law. In a typical OLED device, TIR occurs between organic layers (refractive index around 1.7) and the substrate (refractive index around 1.5); and between the substrate (refractive index around 1.5) and air (refractive index 1.0). In many cases, a large portion of light originating in an emissive layer within an OLED does not escape the device due to TIR at the air interface, edge emission, dissipation within the emissive or other layers, waveguide effects within the emissive layer or other layers of the device (i.e., transporting layers, injection layers, etc.), and other effects. Light generated and/or emitted by an OLED may be described as being in various modes, such as “air mode” (the light will be emitted from a viewing surface of the device, such as through the substrate) or “waveguide mode” (the light is trapped within the device due to waveguide effects). Specific modes may be described with respect to the layer or layers within which the light is trapped, such as “organic mode” (the light is trapped within one or more of the organic layers), “electrode mode” (trapped within an electrode), and “substrate mode” or “glass mode” (trapped within the substrate). These effects result in light trapping in the device and further reduce light extraction efficiency. In a typical OLED, up to 50-60% of light generated by the emissive layer may be trapped in a waveguide mode, and therefore fail to exit the device. Additionally, up to 20-30% of light emitted by the emissive material in a typical OLED can remain in a glass mode. Thus, the outcoupling efficiency of a typical OLED may be as low as about 20%.

There are tremendous efforts to enhance the light outcoupling efficiency of OLEDs by means of various techniques. Most of the light outcoupling techniques are external to the OLED stack, such as substrate surface modifications, external scattering medium (such as, for example, microspheres, micro lenses, gratings, etc.), photonic crystals, micro- and nanocavities, aperiodic dielectric mirrors, and the like. Many of the techniques, however, cause distorted spectra and/or limited viewing angles.

There is an ongoing unresolved need for a good platform system to control properties of hole injection and transport layers, such as solubility, thermal/chemical stability, and electronic energy levels, such as HOMO and LUMO, so that the compounds can be adapted for different applications and to function with different compounds, such as light emitting layers, photoactive layers, and electrodes, while also improving properties such as internal light outcoupling leading to increased efficiency, color saturation, and reduction in changes in luminance and perceived color with viewing angle, for example, in OLEDs.

### SUMMARY OF INVENTION

An objective of the present invention is to provide organic electronic devices having improved light outcoupling effect leading to increased efficiency.

Another objective of the present invention is to provide organic electronic devices having improved color saturation.

Yet another objective of the present invention is to provide organic electronic devices having improved color stability, i.e., reduction in changes in luminance and perceived color with viewing angle.

Therefore, in a first aspect, the present disclosure relates to a device comprising a hole-carrying film, the hole-carrying film comprising:

(a) a polythiophene comprising a repeating unit complying with formula (I)

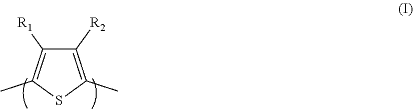

wherein R₁ and R₂ are each, independently, H, alkyl, fluoroalkyl, alkoxy, aryloxy, or —O—[Z—O]ₚ—Rₑ;
wherein
   Z is an optionally halogenated hydrocarbylene group,
   p is equal to or greater than 1, and
   Rₑ is H, alkyl, fluoroalkyl, or aryl; and
      (b) one or more nanoparticles,

wherein the one or more nanoparticles are metallic or metalloid nanoparticles. In a second aspect, the present disclosure relates to the use of one or more nanoparticles to increase the internal light outcoupling in an organic light emitting device comprising the hole-carrying film described herein.

In a third aspect, the present disclosure relates to the use of one or more nanoparticles to enhance the color saturation of an organic light emitting device comprising the hole-carrying film described herein.

In a fourth aspect, the present disclosure relates to the use of one or more nanoparticles to improve color stability of an organic light emitting device comprising the hole-carrying film described herein.

For easy understanding of the present invention, the essential feature and various embodiments of the present invention is enumerated below.

1. A device comprising a hole-carrying film, the hole-carrying film comprising:

(a) a polythiophene comprising a repeating unit complying with formula (I)

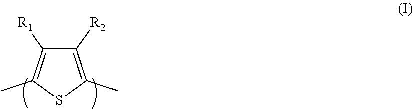

wherein R₁ and R₂ are each, independently, H, alkyl, fluoroalkyl, alkoxy, aryloxy, or —O—[Z—O]ₚ—Rₑ;
wherein
   Z is an optionally halogenated hydrocarbylene group,
   p is equal to or greater than 1, and
   Rₑ is H, alkyl, fluoroalkyl, or aryl; and

(b) one or more nanoparticles,
wherein the one or more nanoparticles are metallic or metalloid nanoparticles.

2. The device according to item 1 above, wherein R₁ and R₂ are each, independently, H, fluoroalkyl, —O[C(RₐR_{b})—C(R_{c}R_{d})—O]ₚ—Rₑ, —OR_{f}; wherein each occurrence of Rₐ, R_{b}, R_{c}, and R_{d} is each, independently, H, halogen, alkyl, fluoroalkyl, or aryl; Rₑ is H, alkyl, fluoroalkyl, or aryl; p is 1, 2, or 3; and R_{f} is alkyl, fluoroalkyl, or aryl.

3. The device according to item 1 or 2 above, wherein R₁ is H and R₂ is other than H.

4. The device according to item 1 or 2 above, wherein R₁ and R₂ are both other than H.

5. The device according to item 4 above, wherein R₁ and R₂ are each, independently, —O[C(RₐR_{b})—C(R_{c}R_{d})—O]ₚ—Rₑ, or —OR_{f}.

6. The device according to item 5 above, wherein R₁ and R₂ are both —O[C(RₐR_{b})—C(R_{c}R_{d})—O]ₚ—Rₑ.

7. The device according to any one of items 2-6 above, wherein each occurrence of Rₐ, R_{b}, R_{c}, and R_{d} is each, independently, H, (C₁-C₈)alkyl, (C₁-C₈)fluoroalkyl, or phenyl; and Rₑ is (C₁-C₈)alkyl, (C₁-C₈)fluoroalkyl, or phenyl.

8. The device according to any one of items 1-7 above, wherein the polythiophene comprises a repeating unit selected from the group consisting of

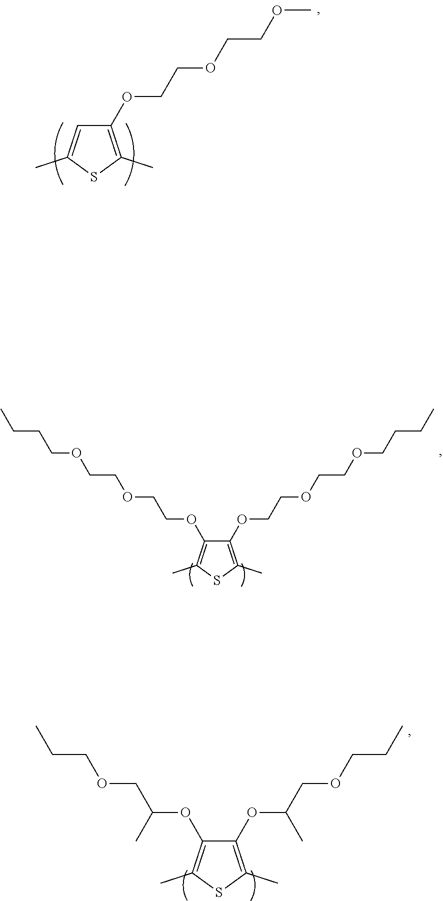

and combinations thereof.

9. The device according to any one of items 1-8 above, wherein the polythiophene is sulfonated.

10. The device according to item 9 above, wherein the polythiophene is sulfonated poly(3-MEET).

11. The device according to any one of items 1-10 above, wherein the polythiophene comprises repeating units complying with formula (I) in an amount of greater than 50% by weight, typically greater than 80% by weight, more typically greater than 90% by weight, even more typically greater than 95% by weight, based on the total weight of the repeating units.

12. The device according to any one of items 1-11 above, wherein one or more nanoparticles are metalloid nanoparticles.

13. The device according to item 12 above, wherein the metalloid nanoparticles comprise B₂O₃, B₂O, SiO₂, SiO, GeO₂, GeO, As₂O₄, As₂O₃, As₂O₅, Sb₂O₃, TeO₂, SnO₂, SnO, or mixtures thereof.

14. The device according to item 13 above, wherein the metalloid nanoparticles comprise SiO₂.

15. The device according to any one of items 1-14 above, wherein the one or more nanoparticles comprise one or more organic capping groups.

16. The device according to any one of items 1-15 above, wherein the amount of the one or more nanoparticles is from 1 wt. % to 98 wt. %, typically from about 2 wt. to about 95 wt. %, more typically from about 5 wt. % to about 90 wt. %, still more typically about 10 wt. % to about 90 wt. %, relative to the combined weight of the nanoparticles and the doped or undoped polythiophene.

17. The device according to any one of items 1-16 above, wherein the hole-carrying film further comprises a synthetic polymer comprising one or more acidic groups.

18. The device according to item 17 above, wherein the synthetic polymer is a polymeric acid comprising one or more repeating units comprising at least one alkyl or alkoxy group which is substituted by at least one fluorine atom and at least one sulfonic acid (—SO₃H) moiety, wherein said alkyl or alkoxy group is optionally interrupted by at least one ether linkage (—O—) group.

19. The device according to item 18 above, wherein the polymeric acid comprises a repeating unit complying with formula (II) and a repeating unit complying with formula (III)

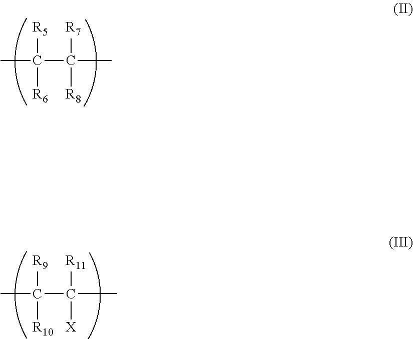

wherein

each occurrence of R₅, R₆, R₇, R₈, R₉, R₁₀, and R₁₁ is, independently, H, halogen, fluoroalkyl, or perfluoroalkyl; and

X is —[OC(RₕRᵢ)—C(RⱼRₖ)]_{q}—O—[CRₗRₘ]_{z}—SO₃H,
wherein each occurrence of Rₕ, Rᵢ, Rⱼ, Rₖ, Rₗ and Rₘ is, independently, H, halogen, fluoroalkyl, or perfluoroalkyl;

q is 0 to 10; and

z is 1-5.

20. The device according to item 17 above, wherein the synthetic polymer is a polyether sulfone comprising one or more repeating units comprising at least one sulfonic acid (—SO₃H) moiety.

21. The device according to item 20 above, wherein the polyether sulfone comprises a repeating unit complying with formula (IV)

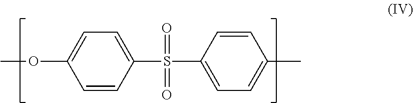

and a repeating unit selected from the group consisting of a repeating unit complying with formula (V) and a repeating unit complying with formula (VI)

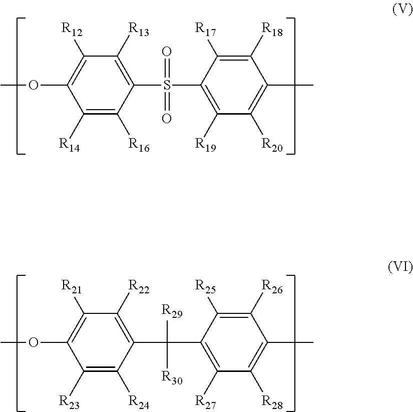

wherein R₁₂-R₂₀ are each, independently, H, halogen, alkyl, or SO₃H, provided that at least one of R₁₂-R₂₀ is SO₃H; and

wherein R₂₁-R₂₈ are each, independently, H, halogen, alkyl, or SO₃H, provided that at least one of R₂₁-R₂₈ is SO₃H, and

R₂₉ and R₃₀ are each H or alkyl.

22. The device according to any one of items 1-21 above, wherein the hole-carrying film further comprises a poly(styrene) or poly(styrene) derivative.

23. The device according to any one of items 1-22 above, wherein the hole-carrying film further comprises one or more amine compounds.

24. The device according to any one of items 1-23 above, wherein the device is an OLED, OPV, transistor, capacitor, sensor, transducer, drug release device, electrochromic device, or battery device.

25. Use of one or more nanoparticles to increase the internal light outcoupling in an organic light emitting device comprising a hole-carrying film, wherein the hole-carrying film comprises a polythiophene comprising a repeating unit complying with formula (I)

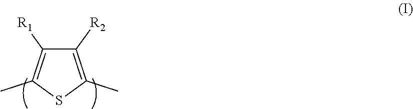

wherein R₁ and R₂ are each, independently, H, alkyl, fluoroalkyl, alkoxy, aryloxy, or —O—[Z—O]ₚ—Rₑ;
wherein
   Z is an optionally halogenated hydrocarbylene group,
   p is equal to or greater than 1, and
      Rₑ is H, alkyl, fluoroalkyl, or aryl; and

wherein the one or more nanoparticles are metallic or metalloid nanoparticles.

26. Use of one or more nanoparticles to enhance the color saturation of an organic light emitting device comprising a hole-carrying film, wherein the hole-carrying film comprises a polythiophene comprising a repeating unit complying with formula (I)

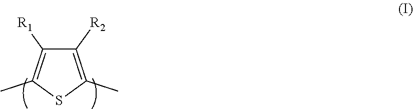

wherein R₁ and R₂ are each, independently, H, alkyl, fluoroalkyl, alkoxy, aryloxy, or —O—[Z—O]ₚ—Rₑ;
wherein
   Z is an optionally halogenated hydrocarbylene group,
   p is equal to or greater than 1, and Rₑ is H, alkyl, fluoroalkyl, or aryl; and

wherein the one or more nanoparticles are metallic or metalloid nanoparticles.

27. Use of one or more nanoparticles to improve color stability of an organic light emitting device comprising a hole-carrying film, wherein the hole-carrying film comprises a polythiophene comprising a repeating unit complying with formula (I)

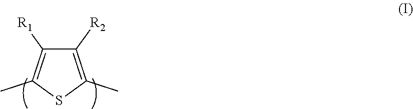

wherein R₁ and R₂ are each, independently, H, alkyl, fluoroalkyl, alkoxy, aryloxy, or —O—[Z—O]ₚ—Rₑ;
wherein
   Z is an optionally halogenated hydrocarbylene group,
   p is equal to or greater than 1, and
      Rₑ is H, alkyl, fluoroalkyl, or aryl; and

wherein the one or more nanoparticles are metallic or metalloid nanoparticles.

28. The use according to any one of items 25-27 above, wherein R₁ and R₂ are each, independently, H, fluoroalkyl, —O[C(RₐR_{b})—C(R_{c}R_{d})—O]ₚ—Rₑ, —OR_{f}; wherein each occurrence of Rₐ, R_{b}, R_{c}, and R_{d} is each, independently, H, halogen, alkyl, fluoroalkyl, or aryl; Rₑ is H, alkyl, fluoroalkyl, or aryl; p is 1, 2, or 3; and R_{f} is alkyl, fluoroalkyl, or aryl.

29. The use according to any one of item 25-28 above, wherein R₁ is H and R₂ is other than H.

30. The use according to any one of items 25-28 above, wherein R₁ and R₂ are both other than H.

31. The use according to item 30 above, wherein R₁ and R₂ are each, independently, —O[C(RₐR_{b})—C(R_{c}R_{d})—O]ₚ—Rₑ, or —OR_{f}.

32. The use according to item 31 above, wherein R₁ and R₂ are both —O[C(RₐR_{b})—C(R_{c}R_{d})—O]ₚ—Rₑ.

33. The use according to any one of items 28-32 above, wherein each occurrence of Rₐ, R_{b}, R_{c}, and R_{d} is each, independently, H, (C₁-C₈)alkyl, (C₁-C₈)fluoroalkyl, or phenyl; and Rₑ is (C₁-C₈)alkyl, (C₁-C₈)fluoroalkyl, or phenyl.

34. The use according to any one of items 25-33 above, wherein the polythiophene comprises a repeating unit selected from the group consisting of

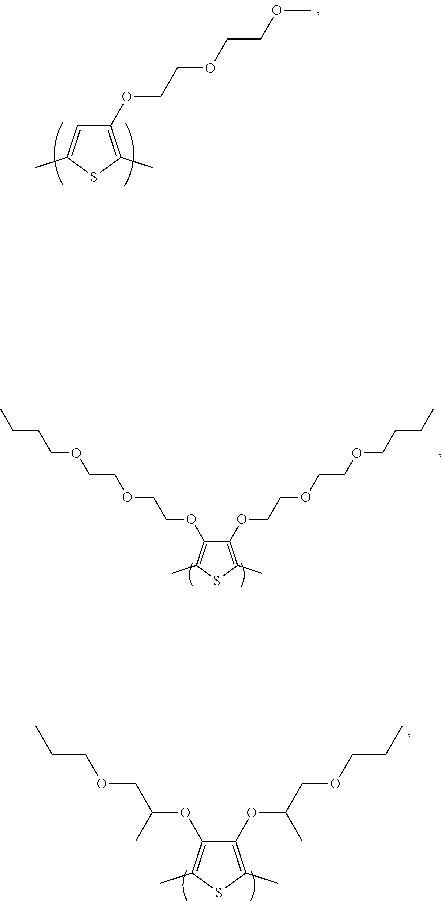

and combinations thereof.

35. The use according to any one of items 25-34 above, wherein the polythiophene is sulfonated.

36. The use according to item 35 above, wherein the polythiophene is sulfonated poly(3-MEET).

37. The use according to any one of items 25-36 above, wherein the polythiophene comprises repeating units complying with formula (I) in an amount of greater than 50% by weight, typically greater than 80% by weight, more typically greater than 90% by weight, even more typically greater than 95% by weight, based on the total weight of the repeating units.

38. The use according to any one of items 25-37 above, wherein one or more nanoparticles are metalloid nanoparticles.

39. The use according to item 38 above, wherein the metalloid nanoparticles comprise B₂O₃, B₂O, SiO₂, SiO, GeO₂, GeO, As₂O₄, As₂O₃, As₂O₅, Sb₂O₃, TeO₂, SnO₂, SnO, or mixtures thereof.

40. The use according to item 39 above, wherein the metalloid nanoparticles comprise SiO₂.

41. The use according to any one of items 25-40 above, wherein the one or more nanoparticles comprise one or more organic capping groups.

42. The use according to any one of items 25-41 above, wherein the amount of the one or more nanoparticles is from 1 wt. % to 98 wt. %, typically from about 2 wt. to about 95 wt. %, more typically from about 5 wt. % to about 90 wt. %, still more typically about 10 wt. % to about 90 wt. %, relative to the combined weight of the nanoparticles and the doped or undoped polythiophene.

43. The use according to any one of items 25-42 above, wherein the hole-carrying film further comprises a synthetic polymer comprising one or more acidic groups.

44. The use according to item 43 above, wherein the synthetic polymer is a polymeric acid comprising one or more repeating units comprising at least one alkyl or alkoxy group which is substituted by at least one fluorine atom and at least one sulfonic acid (—SO₃H) moiety, wherein said alkyl or alkoxy group is optionally interrupted by at least one ether linkage (—O—) group.

45. The use according to item 44 above, wherein the polymeric acid comprises a repeating unit complying with formula (II) and a repeating unit complying with formula (III)

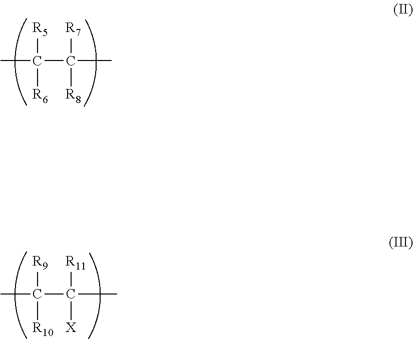

wherein
each occurrence of R₅, R₆, R₇, R₈, R₉, R₁₀, and R₁₁ is, independently, H, halogen, fluoroalkyl, or perfluoroalkyl; and
X is —[OC(RₕRᵢ)—C(RⱼRₖ)]_{q}—O—[CRₗRₘ]_{z}—SO₃H,
   wherein each occurrence of Rₕ, Rᵢ, Rⱼ, Rₖ, Rₗ and Rₘ is, independently, H, halogen, fluoroalkyl, or perfluoroalkyl;
q is 0 to 10; and
z is 1-5.

46. The use according to item 43 above, wherein the synthetic polymer is a polyether sulfone comprising one or more repeating units comprising at least one sulfonic acid (—SO₃H) moiety.

47. The use according to item 46 above, wherein the polyether sulfone comprises a repeating unit complying with formula (IV)

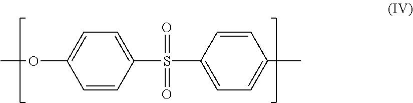

and a repeating unit selected from the group consisting of a repeating unit complying with formula (V) and a repeating unit complying with formula (VI)

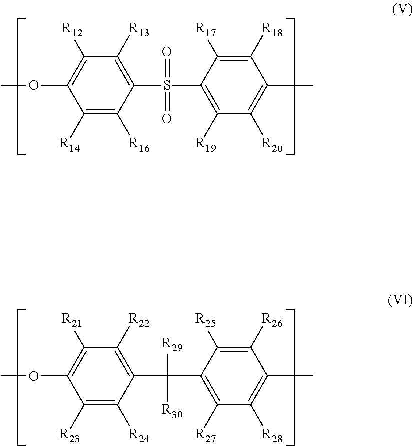

wherein R₁₂-R₂₀ are each, independently, H, halogen, alkyl, or SO₃H, provided that at least one of R₁₂-R₂₀ is SO₃H; and
wherein R₂₁-R₂₈ are each, independently, H, halogen, alkyl, or SO₃H, provided that at least one of R₂₁-R₂₈ is SO₃H, and
R₂₉ and R₃₀ are each H or alkyl.

48. The use according to any one of items 25-47 above, wherein the hole-carrying film further comprises a poly(styrene) or poly(styrene) derivative.

49. The use according to any one of items 25-48 above, wherein the hole-carrying film further comprises one or more amine compounds.

50. A non-aqueous ink composition comprising:

(a) a sulfonated polythiophene comprising a repeating unit complying with formula (I):

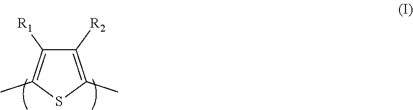

wherein R₁ and R₂ are each, independently, H, alkyl, fluoroalkyl, alkoxy, aryloxy, or —O— [Z—O]ₚ—Rₑ;

wherein
Z is an optionally halogenated hydrocarbylene group,
p is equal to or greater than 1, and
Rₑ is H, alkyl, fluoroalkyl, or aryl;

(b) one or more amine compounds;

(c) one or more metalloid nanoparticles;

(d) optionally a synthetic polymer comprising one or more acidic groups; and

(e) a liquid carrier which is 1) or 2) below:
1) a liquid carrier consisting of (A) one or more glycol-based solvents, and
2) a liquid carrier comprising (A) one or more glycol-based solvents and

(B) one or more organic solvents other than the glycol-based solvents.

51. The non-aqueous ink composition according to item 50 above, wherein the liquid carrier is a liquid carrier comprising (A) one or more glycol-based solvents and (B) one or more organic solvents other than the glycol-based solvents.

52. The non-aqueous ink composition according to item 50 or 51 above, wherein the glycol-based solvent (A) is a glycol ether, glycol monoether or glycol.

53. The non-aqueous ink composition according to any one of items 50 to 52 above, wherein the organic solvent (B) is a nitrile, alcohol, aromatic ether or aromatic hydrocarbon.

54. The non-aqueous ink composition according to any one of items 50 to 53 above, wherein the proportion by weight (wtA) of the glycol-based solvent (A) and the proportion by weight (wtB) of the organic solvent (B) satisfy the relationship represented by the following formula (1-1):

0.05≤wtB/(wtA+wtB)≤0.50 (1-1).

55. The non-aqueous ink composition according to any one of items 50 to 54 above, wherein R₁ and R₂ are each, independently, H, fluoroalkyl, —O[C(RₐR_{b})—C(R_{c}R_{d})—O]ₚ—Rₑ, —OR_{f}; wherein each occurrence of Rₐ, R_{b}, R_{c}, and R_{d} is each, independently, H, halogen, alkyl, fluoroalkyl, or aryl; Rₑ is H, alkyl, fluoroalkyl, or aryl; p is 1, 2, or 3; and R_{f} is alkyl, fluoroalkyl, or aryl.

56. The non-aqueous ink composition according to any one of items 50 to 55 above, wherein R₁ is H and R₂ is other than H.

57. The non-aqueous ink composition according to any one of items 50 to 55 above, wherein R₁ and R₂ are both other than H.

58. The non-aqueous ink composition according to item 57 above, wherein R₁ and R₂ are each, independently, —O[C(RₐR_{b})—C(R_{c}R_{d})—O]—Rₑ, or —OR_{f}.

59. The non-aqueous ink composition according to item 58 above, wherein R₁ and R₂ are both —O[C(RₐR_{b})—C(R_{c}R_{d})—O]ₚ—Rₑ.

60. The non-aqueous ink composition according to any one of items 55 to 59 above, wherein each occurrence of R_{d}, R_{b}, R_{c}, and R_{d} is each, independently, H, (C₁-C₈)alkyl, (C₁-C₈)fluoroalkyl, or phenyl; and Rₑ is (C₁-C₈)alkyl, (C₁-C₈)fluoroalkyl, or phenyl.

61. The non-aqueous ink composition according to any one of items 50 to 60 above, wherein the polythiophene comprises a repeating unit selected from the group consisting of

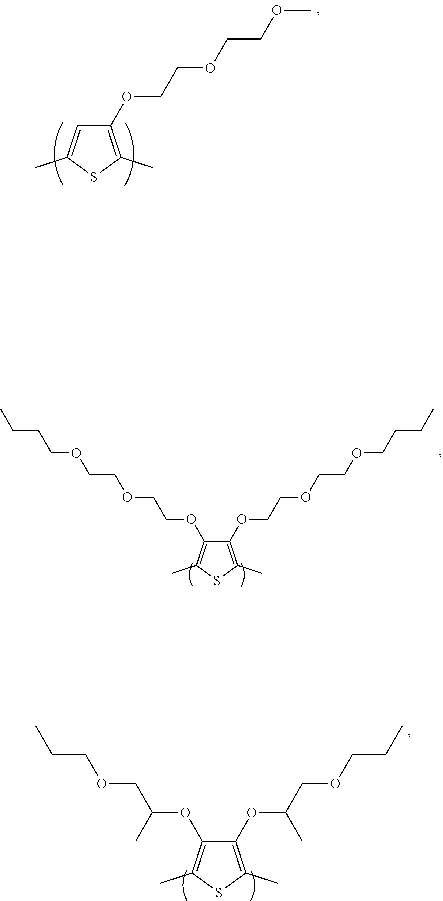

and combinations thereof.

62. The non-aqueous ink composition according to any one of items 50 to 61 above, wherein the sulfonated polythiophene is sulfonated poly(3-MEET).

63. The non-aqueous ink composition according to any one of items 50 to 62 above, wherein the amine compound is a tertiary alkylamine compound.

64. The non-aqueous ink composition according to item 63 above, wherein the tertiary alkylamine compound is triethylamine.

65. The non-aqueous ink composition according to any one of items 50 to 64 above, wherein the metalloid nanoparticles comprise B₂O₃, B₂O, SiO₂, SiO, GeO₂, GeO, As₂O₄, As₂O₃, As₂O₅, Sb₂O₃, TeO₂, SnO₂, SnO, or mixtures thereof.

66. The non-aqueous ink composition according to item 65 above, wherein the metalloid nanoparticles comprise SiO₂.

67. The non-aqueous ink composition according to any one of items 50 to 66 above, which comprises the synthetic polymer comprising one or more acidic groups.

68. The non-aqueous ink composition according to item 67 above, wherein the synthetic polymer is a polymeric acid comprising one or more repeating units comprising at least one alkyl or alkoxy group which is substituted by at least one fluorine atom and at least one sulfonic acid (—SO₃H) moiety, wherein said alkyl or alkoxy group is optionally interrupted by at least one ether linkage (—O—) group.

69. The non-aqueous ink composition according to item 68 above, wherein the polymeric acid comprises a repeating unit complying with formula (II) and a repeating unit complying with formula (III)

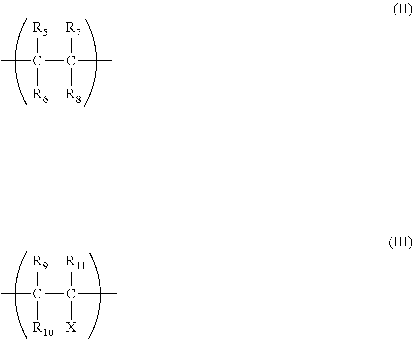

wherein
each occurrence of R₅, R₆, R₇, R₈, R₉, R₁₀, and R₁₁ is, independently, H, halogen, fluoroalkyl, or perfluoroalkyl; and
X is —[OC(RₕRᵢ)—C(RⱼRₖ)]_{q}—O—[CRₗRₘ]_{z}—SO₃H,
   wherein each occurrence of Rₕ, Rᵢ, Rⱼ, Rₖ, Rₗ and Rₘ is, independently, H, halogen, fluoroalkyl, or perfluoroalkyl;
q is 0 to 10; and
z is 1-5.

### BRIEF DESCRIPTION OF DRAWINGS

FIG. 1 shows the current density as a function of voltage for the green OLED having HIL made from NQ ink 1 and the green OLED having HIL made from Comparative NQ ink.

FIG. 2 shows the % EQE as a function of luminance for the green OLED having HIL made from NQ ink 1 and the green OLED having HIL made from Comparative NQ ink.

FIG. 3A shows the electroluminescence spectra of the green OLED having HIL made from Comparative NQ ink determined at various incident angles.

FIG. 3B shows the electroluminescence spectra of the green OLED having HIL made from NQ ink 1 determined at various incident angles.

FIG. 4 shows the CIE x coordinates of the green OLED having HIL made from Comparative NQ ink and the CIE x coordinates of the green OLED having HIL made from inventive ink 1 as a function of incident angle.

FIG. 5 shows the CIE y coordinates of the green OLED having HIL made from Comparative NQ ink and the CIE y coordinates of the green OLED having HIL made from inventive ink 1 as a function of incident angle.

FIG. 6A shows the EL spectra of the blue OLED having HIL made from Comparative AQ ink determined at various incident angles.

FIG. 6B shows the EL spectra of the blue OLED having HIL made from NQ ink 2 determined at various incident angles.

FIG. 7 shows a radial plot of brightness vs. incident angle of the blue OLED having an HIL made from NQ ink 2 and the blue OLED having an HIL made from Comparative AQ ink.

FIG. 8 shows a comparison of the refractive index of an HIL prepared from NQ ink 1, an HIL prepared from Comparative NQ ink, and the refractive index of SiO2 versus wavelength.

### DESCRIPTION OF EMBODIMENTS

As used herein, the terms “a”, “an”, or “the” means “one or more” or “at least one” unless otherwise stated.

As used herein, the term “comprises” includes “consists essentially of” and “consists of.” The term “comprising” includes “consisting essentially of” and “consisting of.”

The phrase “free of” means that there is no external addition of the material modified by the phrase and that there is no detectable amount of the material that may be observed by analytical techniques known to the ordinarily-skilled artisan, such as, for example, gas or liquid chromatography, spectrophotometry, optical microscopy, and the like.

Throughout the present disclosure, various publications may be incorporated by reference. Should the meaning of any language in such publications incorporated by reference conflict with the meaning of the language of the present disclosure, the meaning of the language of the present disclosure shall take precedence, unless otherwise indicated.

As used herein, the terminology “(Cx-Cy)” in reference to an organic group, wherein x and y are each integers, means that the group may contain from x carbon atoms to y carbon atoms per group.

As used herein, the term “hydrocarbyl” means a monovalent radical formed by removing one hydrogen atom from a hydrocarbon, typically a (C₁-C₄₀) hydrocarbon, more typically a (C₁-C₃₀) hydrocarbon. Hydrocarbyl groups may be straight, branched or cyclic, and may be saturated or unsaturated. Examples of hydrocarbyl groups include, but are not limited to, alkyl, alkenyl, alkynyl, cycloalkyl, and aryl.

As used herein, the term “hydrocarbylene” means a divalent radical formed by removing two hydrogen atoms from a hydrocarbon, typically a (C₁-C₄₀) hydrocarbon. Hydrocarbylene groups may be straight, branched or cyclic, and may be saturated or unsaturated. Examples of hydrocarbylene groups include, but are not limited to, methylene, ethylene, 1-methylethylene, 1-phenylethylene, propylene, butylene, 1,2-benzene; 1,3-benzene; 1,4-benzene; and 2,6-naphthalene.

As used herein, the term “alkyl” means a monovalent straight or branched saturated hydrocarbon radical, more typically, a monovalent straight or branched saturated (C₁-C₄₀)hydrocarbon radical, such as, for example, methyl, ethyl, n-propyl, isopropyl, n-butyl, isobutyl, tert-butyl, hexyl, 2-ethylhexyl, octyl, hexadecyl, octadecyl, eicosyl, behenyl, tricontyl, and tetracontyl. As used herein, the term “cycloalkyl” means a monovalent saturated cyclic hydrocarbon radical, more typically a saturated cyclic (C₅-C₂₂) hydrocarbon radical, such as, for example, cyclopentyl, cycloheptyl, cyclooctyl.

As used herein, the term “fluoroalkyl” means an alkyl radical as defined herein, more typically a (C₁-C₄₀) alkyl radical that is substituted with one or more fluorine atoms. Examples of fluoroalkyl groups include, for example, difluoromethyl, trifluoromethyl, perfluoroalkyl, 1H,1H,2H,2H-perfluorooctyl, perfluoroethyl, and —CH₂CF₃.

As used herein, the term “aryl” means a monovalent group having at least one aromatic ring. As understood by the ordinarily-skilled artisan, an aromatic ring has a plurality of carbon atoms, arranged in a ring and has a delocalized conjugated Jr electron system, typically represented by alternating single and double bonds. Aryl radicals include monocyclic aryl and polycyclic aryl. Polycyclic aryl means a monovalent group having two or more aromatic rings wherein adjacent rings may be linked to each other by one or more bonds or divalent bridging groups or may be fused together. Examples of aryl radicals include, but are not limited to, phenyl, anthracenyl, naphthyl, phenanthrenyl, fluorenyl, and pyrenyl.

As used herein, the term “aryloxy” means a monovalent radical denoted as —O-aryl, wherein the aryl group is as defined herein. Examples of aryloxy groups, include, but are not limited to, phenoxy, anthracenoxy, naphthoxy, phenanthrenoxy, and fluorenoxy.

As used herein, the term “alkoxy” means a monovalent radical denoted as —O-alkyl, wherein the alkyl group is as defined herein. Examples of alkoxy groups, include, but are not limited to, methoxy, ethoxy, n-propoxy, isopropoxy, n-butoxy, isobutoxy, and tert-butoxy.

Any substituent or radical described herein may optionally be substituted at one or more carbon atoms with one or more, same or different, substituents described herein. For instance, a hydrocarbyl group may be further substituted with an aryl group or an alkyl group. Any substituent or radical described herein may also optionally be substituted at one or more carbon atoms with one or more substituents selected from the group consisting of halogen, such as, for example, F, Cl, Br, and I; nitro (NO₂), cyano (CN), and hydroxy (OH). When a substituent or radical described herein is substituted at one or more carbon atoms with one or more substituents selected from the group consisting of halogen, such as, for example, F, Cl, Br, and I, the substituent or radical is said to be halogenated.

As used herein, the term “hole carrier compound” refers to any compound that is capable of facilitating the movement of holes, i.e., positive charge carriers, and/or blocking the movement of electrons, for example, in an electronic device. Hole carrier compounds include compounds useful in layers (HTLs), hole injection layers (HILs) and electron blocking layers (EBLs) of electronic devices, typically organic electronic devices, such as, for example, organic light emitting devices.

As used herein, the term “doped” in reference to a hole carrier compound, for example, a polythiophene polymer, means that the hole carrier compound has undergone a chemical transformation, typically an oxidation or reduction reaction, more typically an oxidation reaction, facilitated by a dopant. As used herein, the term “dopant” refers to a substance that oxidizes or reduces, typically oxidizes, a hole carrier compound, for example, a polythiophene polymer. Herein, the process wherein a hole carrier compound undergoes a chemical transformation, typically an oxidation or reduction reaction, more typically an oxidation reaction, facilitated by a dopant is called a “doping reaction” or simply “doping”. Doping alters the properties of the polythiophene polymer, which properties may include, but may not be limited to, electrical properties, such as resistivity and work function, mechanical properties, and optical properties. In the course of a doping reaction, the hole carrier compound becomes charged, and the dopant, as a result of the doping reaction, becomes the oppositely-charged counterion for the doped hole carrier compound. As used herein, a substance must chemically react, oxidize or reduce, typically oxidize, a hole carrier compound to be referred to as a dopant. Substances that do not react with the hole carrier compound but may act as counterions are not considered dopants according to the present disclosure. Accordingly, the term “undoped” in reference to a hole carrier compound, for example a polythiophene polymer, means that the hole carrier compound has not undergone a doping reaction as described herein.

The present disclosure relates to a device comprising a hole-carrying film, the hole-carrying film comprising:

(a) a polythiophene comprising a repeating unit complying with formula (I)

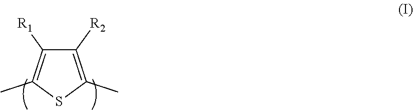

wherein R₁ and R₂ are each, independently, H, alkyl, fluoroalkyl, alkoxy, aryloxy, or —O—[Z—O]ₚ—Rₑ;
wherein
   Z is an optionally halogenated hydrocarbylene group,
   p is equal to or greater than 1, and
   Rₑ is H, alkyl, fluoroalkyl, or aryl; and

(b) one or more nanoparticles,
wherein the one or more nanoparticles are metallic or metalloid nanoparticles.

The polythiophene suitable for use according to the present disclosure comprises a repeating unit complying with formula (I)

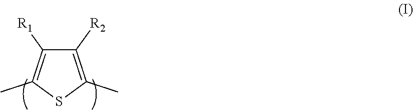

wherein R₁ and R₂ are each, independently, H, alkyl, fluoroalkyl, alkoxy, aryloxy, or —O—[Z—O]ₚ—Rₑ; wherein Z is an optionally halogenated hydrocarbylene group, p is equal to or greater than 1, and Rₑ is H, alkyl, fluoroalkyl, or aryl.

In an embodiment, R₁ and R₂ are each, independently, H, fluoroalkyl, —O[C(RₐR_{b})—C(R_{c}R_{d})—O]ₚ—Rₑ, —OR_{f}; wherein each occurrence of Rₐ, R_{b}, Rₑ, and R_{d} is each, independently, H, halogen, alkyl, fluoroalkyl, or aryl; Rₑ is H, alkyl, fluoroalkyl, or aryl; p is 1, 2, or 3; and R_{f} is alkyl, fluoroalkyl, or aryl.

In an embodiment, R₁ is H and R₂ is other than H. In such an embodiment, the repeating unit is derived from a 3-substituted thiophene.

The polythiophene can be a regiorandom or a regioregular compound. Due to its asymmetrical structure, the polymerization of 3-substituted thiophenes produces a mixture of polythiophene structures containing three possible regiochemical linkages between repeat units. The three orientations available when two thiophene rings are joined are the 2,2′; 2,5′, and 5,5′ couplings. The 2,2′ (or head-to-head) coupling and the 5,5′ (or tail-to-tail) coupling are referred to as regiorandom couplings. In contrast, the 2,5′ (or head-to-tail) coupling is referred to as a regioregular coupling. The degree of regioregularity can be, for example, about 0 to 100%, or about 25 to 99.9%, or about 50 to 98%. Regioregularity may be determined by standard methods known to those of ordinary skill in the art, such as, for example, using NMR spectroscopy.

In an embodiment, the polythiophene is regioregular. In some embodiments, the regioregularity of the polythiophene can be at least about 85%, typically at least about 95%, more typically at least about 98%. In some embodiments, the degree of regioregularity can be at least about 70%, typically at least about 80%. In yet other embodiments, the regioregular polythiophene has a degree of regioregularity of at least about 90%, typically a degree of regioregularity of at least about 98%.

3-substituted thiophene monomers, including polymers derived from such monomers, are commercially-available or may be made by methods known to those of ordinary skill in the art. Synthetic methods, doping, and polymer characterization, including regioregular polythiophenes with side groups, is provided in, for example, U.S. Pat. No. 6,602,974 to McCullough et al. and U.S. Pat. No. 6,166,172 to McCullough et al.

In another embodiment, R₁ and R₂ are both other than H. In such an embodiment, the repeating unit is derived from a 3,4-disubstituted thiophene.

In an embodiment, R₁ and R₂ are each, independently, —O[C(RₐR_{b})—C(R_{c}R_{d})—O]ₚ—Rₑ, or —OR_{f}. In an embodiment, R₁ and R₂ are both —O[C(RₐR_{b})—C(R_{c}R_{d})—O]ₚ—Rₑ. R₁ and R₂ may be the same or different.

In an embodiment, each occurrence of Rₐ, R_{b}, R_{c}, and R_{d} is each, independently, H, (C₁-C₈)alkyl, (C₁-C₈)fluoroalkyl, or phenyl; and Rₑ is (C₁-C₈)alkyl, (C₁-C₈)fluoroalkyl, or phenyl.

In an embodiment, R₁ and R₂ are each —O[CH₂—CH₂—O]ₚ—Rₑ. In an embodiment, R₁ and R₂ are each —O[CH(CH₃)—CH₂—O]ₚ—Rₑ.

In an embodiment, Rₑ is methyl, propyl, or butyl.

In an embodiment, the polythiophene comprises a repeating unit selected from the group consisting of

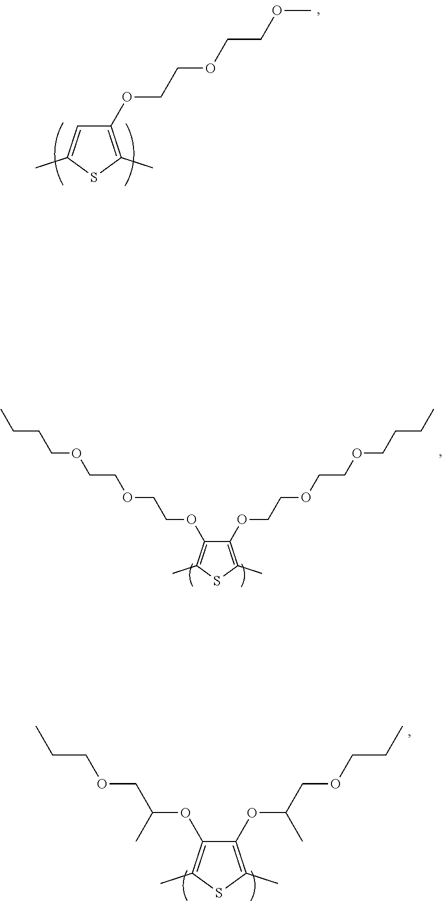

and combinations thereof.

It would be understood by the ordinarily-skilled artisan that the repeating unit

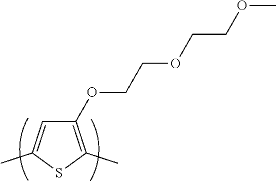

is derived from a monomer represented by the structure

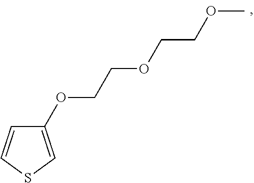

3-(2-(2-methoxyethoxy)ethoxy)thiophene [referred to herein as 3-MEET]; the repeating unit

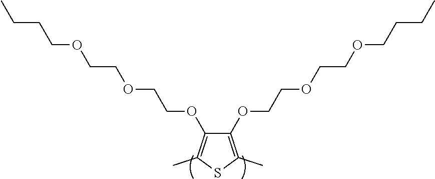

is derived from a monomer represented by the structure

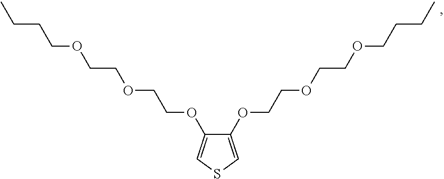 [SMILES: CCCCOCCOCCOc1cscc1OCCOCCOCCCC]

3,4-bis(2-(2-butoxyethoxy)ethoxy)thiophene [referred to herein as 3,4-diBEET]; and the repeating unit

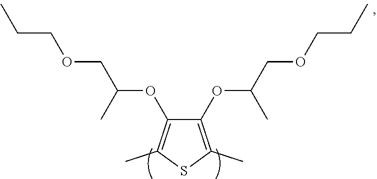

is derived from a monomer represented by the structure

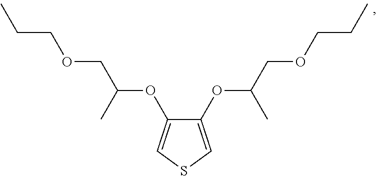 [SMILES: CCCOCC(C)Oc1cscc1OC(C)COCCC]

3,4-bis((1-propoxypropan-2-yl)oxy)thiophene [referred to herein as 3,4-diPPT].

3,4-disubstituted thiophene monomers, including polymers derived from such monomers, are commercially-available or may be made by methods known to those of ordinary skill in the art. For example, a 3,4-disubstituted thiophene monomer may be produced by reacting 3,4-dibromothiophene with the metal salt, typically sodium salt, of a compound given by the formula HO—[Z—O]ₚ—Rₑ or HOR_{f}, wherein Z, Rₑ, R_{f} and p are as defined herein.

The polymerization of 3,4-disubstituted thiophene monomers may be carried out by, first, brominating the 2 and 5 positions of the 3,4-disubstituted thiophene monomer to form the corresponding 2,5-dibromo derivative of the 3,4-disubstituted thiophene monomer. The polymer can then be obtained by GRIM (Grignard methathesis) polymerization of the 2,5-dibromo derivative of the 3,4-disubstituted thiophene in the presence of a nickel catalyst. Such a method is described, for example, in U.S. Pat. No. 8,865,025, the entirety of which is hereby incorporated by reference. Another known method of polymerizing thiophene monomers is by oxidative polymerization using organic non-metal containing oxidants, such as 2,3-dichloro-5,6-dicyano-1,4-benzoquinone (DDQ), or using a transition metal halide, such as, for example, iron(III) chloride, molybdenum(V) chloride, and ruthenium(III) chloride, as oxidizing agent.

Examples of compounds having the formula HO—[Z—O]ₚ—Rₑ or HOR_{f} that may be converted to the metal salt, typically sodium salt, and used to produce 3,4-disubstituted thiophene monomers include, but are not limited to, trifluoroethanol, ethylene glycol monohexyl ether (hexyl Cellosolve), propylene glycol monobutyl ether (Dowanol PnB), diethylene glycol monoethyl ether (ethyl Carbitol), dipropylene glycol n-butyl ether (Dowanol DPnB), diethylene glycol monophenyl ether (phenyl Carbitol), ethylene glycol monobutyl ether (butyl Cellosolve), diethylene glycol monobutyl ether (butyl Carbitol), dipropylene glycol monomethyl ether (Dowanol DPM), diisobutyl carbinol, 2-ethylhexyl alcohol, methyl isobutyl carbinol, ethylene glycol monophenyl ether (Dowanol Eph), propylene glycol monopropyl ether (Dowanol PnP), propylene glycol monophenyl ether (Dowanol PPh), diethylene glycol monopropyl ether (propyl Carbitol), diethylene glycol monohexyl ether (hexyl Carbitol), 2-ethylhexyl carbitol, dipropylene glycol monopropyl ether (Dowanol DPnP), tripropylene glycol monomethyl ether (Dowanol TPM), diethylene glycol monomethyl ether (methyl Carbitol), and tripropylene glycol monobutyl ether (Dowanol TPnB).

The polythiophene having a repeating unit complying with formula (I) of the present disclosure may be further modified subsequent to its formation by polymerization. For instance, polythiophenes having one or more repeating units derived from 3-substituted thiophene monomers may possess one or more sites where hydrogen may be replaced by a substituent, such as a sulfonic acid group (—SO₃H) by sulfonation.

As used herein, the term “sulfonated” in relation to the polythiophene polymer means that the polythiophene comprises one or more sulfonic acid groups (—SO₃H) (such a polythiophene may be referred to also as a “sulfonated polythiophene”). Typically, the sulfur atom of the —SO₃H group is directly bonded to the backbone of the polythiophene polymer and not to a side group. For the purpose of the present disclosure, a side group is a monovalent radical that when theoretically or actually removed from the polymer does not shorten the length of the polymer chain. The sulfonated polythiophene polymer and/or copolymer may be made using any method known to those of ordinary skill in the art. For example, the polythiophene may be sulfonated by reacting the polythiophene with a sulfonating reagent such as, for example, fuming sulfuric acid, acetyl sulfate, pyridine SO₃, or the like. In another example, monomers may be sulfonated using a sulfonating reagent and then polymerized according to known methods and/or methods described herein. It would be understood by the ordinarily-skilled artisan that sulfonic acid groups in the presence of a basic compound, for example, alkali metal hydroxides, ammonia, and alkylamines, such as, for example, mono-, di-, and trialkylamines, such as, for example, triethylamine, may result in the formation of the corresponding salt or adduct. Thus, the term “sulfonated” in relation to the polythiophene polymer includes the meaning that the polythiophene may comprise one or more —SO₃M groups, wherein M may be an alkali metal ion, such as, for example, Na⁺, Li⁺, K⁺, R_{b}⁺, Cs⁺; ammonium (NH₄⁺), mono-, di-, and trialkylammonium, such as triethylammonium.

The sulfonation of conjugated polymers and sulfonated conjugated polymers, including sulfonated polythiophenes, are described in U.S. Pat. No. 8,017,241 to Seshadri et al., which is incorporated herein by reference in its entirety.

In an embodiment, the polythiophene is sulfonated.

In an embodiment, the polythiophene is sulfonated poly(3-MEET).

The polythiophene polymers used according to the present disclosure may be homopolymers or copolymers, including statistical, random, gradient, and block copolymers. For a polymer comprising a monomer A and a monomer B, block copolymers include, for example, A-B diblock copolymers, A-B-A triblock copolymers, and -(AB)ₙ-multiblock copolymers. The polythiophene may comprise repeating units derived from other types of monomers such as, for example, thienothiophenes, selenophenes, pyrroles, furans, tellurophenes, anilines, arylamines, and arylenes, such as, for example, phenylenes, phenylene vinylenes, and fluorenes.

In an embodiment, the polythiophene comprises repeating units complying with formula (I) in an amount of greater than 50% by weight, typically greater than 80% by weight, more typically greater than 90% by weight, even more typically greater than 95% by weight, based on the total weight of the repeating units.

It would be clear to a person of ordinary skill in the art that, depending on the purity of the starting monomer compound(s) used in the polymerization, the polymer formed may contain repeating units derived from impurities. As used herein, the term “homopolymer” is intended to mean a polymer comprising repeating units derived from one type of monomer, but may contain repeating units derived from impurities. In an embodiment, the polythiophene is a homopolymer wherein essentially all of the repeating units are repeating units complying with formula (I).

The polythiophene polymer typically has a number average molecular weight between about 1,000 and 1,000,000 g/mol. More typically, the conjugated polymer has a number average molecular weight between about 5,000 and 100,000 g/mol, even more typically about 10,000 to about 50,000 g/mol. Number average molecular weight may be determined according to methods known to those of ordinary skill in the art, such as, for example, by gel permeation chromatography.

The hole-carrying film of the device according to the present disclosure may optionally further comprise other hole carrier compounds.

Optional hole carrier compounds include, for example, low molecular weight compounds or high molecular weight compounds. The optional hole carrier compounds may be non-polymeric or polymeric. Non-polymeric hole carrier compounds include, but are not limited to, cross-linkable and non-crosslinked small molecules. Examples of non-polymeric hole carrier compounds include, but are not limited to, N,N′-bis(3-methylphenyl)-N,N′-bis(phenyl)benzidine (CAS #65181-78-4); N,N′-bis(4-methylphenyl)-N,N′-bis(phenyl)benzidine; N,N′-bis(2-naphtalenyl)-N—N′-bis(phenylbenzidine) (CAS #139255-17-1); 1,3,5-tris(3-methyldiphenylamino)benzene (also referred to as m-MTDAB); N,N′-bis(1-naphtalenyl)-N,N′-bis(phenyl)benzidine (CAS #123847-85-8, NPB); 4,4′,4‘ ’-tris(N,N-phenyl-3-methylphenylamino)triphenylamine (also referred to as m-MTDATA, CAS #124729-98-2); 4,4′,N,N′-diphenylcarbazole (also referred to as CBP, CAS #58328-31-7); 1,3,5-tris(diphenylamino)benzene; 1,3,5-tris(2-(9-ethylcarbazyl-3)ethylene)benzene; 1,3,5-tris [(3-methylphenyl)phenylamino]benzene; 1,3-bis(N-carbazolyl)benzene; 1,4-bis(diphenylamino)benzene; 4,4′-bis(N-carbazolyl)-1,1′-biphenyl; 4,4′-bis(N-carbazolyl)-1,1′-biphenyl; 4-(dibenzylamino)benzaldehyde-N,N-diphenylhydrazone; 4-(diethylamino)benzaldehyde diphenylhydrazone; 4-(dimethylamino)benzaldehyde diphenylhydrazone; 4-(diphenylamino)benzaldehyde diphenylhydrazone; 9-ethyl-3-carbazolecarboxaldehyde diphenylhydrazone; copper(II) phthalocyanine; N,N′-bis(3-methylphenyl)-N,N′-diphenylbenzidine; N,N′-di-[(1-naphthyl)-N,N′-diphenyl]-1,1′-biphenyl)-4,4′-diamine; N,N′-diphenyl-N,N′-di-p-tolylbenzene-1,4-diamine; tetra-N-phenylbenzidine; titanyl phthalocyanine; tri-p-tolylamine; tris(4-carbazol-9-ylphenyl)amine; and tris[4-(di-ethylamino)phenyl]amine.

Optional polymeric hole carrier compounds include, but are not limited to, poly[(9,9-dihexylfluorenyl-2,7-diyl)-alt-co-(N,N′bis {p-butylphenyl}-1,4-diaminophen ylene)];

poly[(9,9-dioctylfluorenyl-2,7-diyl)-alt-co-(N,N′-bis {p-butylphenyl}-1,1′-biphenylene-4,4′-diamine)]; poly(9,9-dioctylfluorene-co-N-(4-butylphenyl)diphenylamine) (also referred to as TFB) and poly[N,N′-bis(4-butylphenyl)-N,N′-bis(phenyl)-benzidine](commonly referred to as poly-TPD).

Other optional hole carrier compounds are described in, for example, US Patent Publications 2010/0292399 published Nov. 18, 2010; 2010/010900 published May 6, 2010; and 2010/0108954 published May 6, 2010. Optional hole carrier compounds described herein are known in the art and are commercially available.

The polythiophene comprising a repeating unit complying with formula (I) may be doped or undoped.

In an embodiment, the polythiophene comprising a repeating unit complying with formula (I) is doped with a dopant. Dopants are known in the art. See, for example, U.S. Pat. No. 7,070,867; US Publication 2005/0123793; and US Publication 2004/0113127. The dopant can be an ionic compound. The dopant can comprise a cation and an anion. One or more dopants may be used to dope the polythiophene comprising a repeating unit complying with formula (I).

The cation of the ionic compound can be, for example, V, Cr, Mn, Fe, Co, Ni, Cu, Nb, Mo, Tc, Ru, Rh, Pd, Ag, Ta, W, Re, Os, Ir, Pt, or Au.

The cation of the ionic compound can be, for example, gold, molybdenum, rhenium, iron, and silver cation.

In some embodiments, the dopant can comprise a sulfonate or a carboxylate, including alkyl, aryl, and heteroaryl sulfonates and carboxylates. As used herein, “sulfonate” refers to a —SO₃M group, wherein M may be H⁺ or an alkali metal ion, such as, for example, Na⁺, Li⁺, K⁺, R_{b}⁺, Cs⁺; or ammonium (NH₄⁺). As used herein, “carboxylate” refers to a —CO₂M group, wherein M may be H⁺ or an alkali metal ion, such as, for example, Na⁺, Li⁺, K⁺, R_{b}⁺, Cs⁺; or ammonium (NH₄⁺). Examples of sulfonate and carboxylate dopants include, but are not limited to, benzoate compounds, heptafluorobutyrate, methanesulfonate, trifluoromethanesulfonate, p-toluenesulfonate, pentafluoropropionate, and polymeric sulfonates, perfluorosulfonate-containing ionomers, and the like.

In some embodiments, the dopant does not comprise a sulfonate or a carboxylate.

In some embodiments, dopants may comprise sulfonylimides, such as, for example, bis(trifluoromethanesulfonyl)imide; antimonates, such as, for example, hexafluoroantimonate; arsenates, such as, for example, hexafluoroarsenate; phosphorus compounds, such as, for example, hexafluorophosphate; and borates, such as, for example, tetrafluoroborate, tetraarylborates, and trifluoroborates. Examples of tetraarylborates include, but are not limited to, halogenatedtetraarylborates, such as tetrakispentafluorophenylborate (TPFB). Examples of trifluoroborates include, but are not limited to, (2-nitrophenyl)trifluoroborate, benzofurazan-5-trifluoroborate, pyrimidine-5-trifluoroborate, pyridine-3-trifluoroborate, and 2,5-dimethylthiophene-3-trifluoroborate.

As disclosed herein, the polythiophene can be doped with a dopant. A dopant can be, for example, a material that will undergo one or more electron transfer reaction(s) with, for example, a conjugated polymer, thereby yielding a doped polythiophene. The dopant can be selected to provide a suitable charge balancing counter-anion. A reaction can occur upon mixing of the polythiophene and the dopant as known in the art. For example, the dopant may undergo spontaneous electron transfer from the polymer to a cation-anion dopant, such as a metal salt, leaving behind a conjugated polymer in its oxidized form with an associated anion and free metal. See, for example, Lebedev et al., Chem. Mater., 1998, 10, 156-163. As disclosed herein, the polythiophene and the dopant can refer to components that will react to form a doped polymer. The doping reaction can be a charge transfer reaction, wherein charge carriers are generated, and the reaction can be reversible or irreversible. In some embodiments, silver ions may undergo electron transfer to or from silver metal and the doped polymer.

The final composition resulting from the doping process can be distinctly different from the combination of original components, i.e., the polythiophene and/or dopant may or may not be present in the composition in the same form before mixing.

Some embodiments allow for removal of reaction by-products from the doping process. For example, the metals, such as silver, can be removed by filtration.

Materials can be purified to remove, for example, halogens and metals. Halogens include, for example, chloride, bromide and iodide. Metals include, for example, the cation of the dopant, including the reduced form of the cation of the dopant, or metals left from catalyst or initiator residues. Metals include, for example, silver, nickel, and magnesium. The amounts can be less than, for example, 100 ppm, or less than 10 ppm, or less than 1 ppm.

Metal content, including silver content, can be measured by ICP-MS, particularly for concentrations greater than 50 ppm.

In an embodiment, when the polythiophene is doped with a dopant, the polythiophene and the dopant are mixed to form a doped polymer composition. Mixing may be achieved using any method known to those of ordinary skill in the art. For example, a solution comprising the polythiophene may be mixed with a separate solution comprising the dopant. The solvent or solvents used to dissolve the polythiophene and the dopant may be one or more solvents described herein. A reaction can occur upon mixing of the polythiophene and the dopant as known in the art. The resulting doped polythiophene composition comprises between about 40% and 75% by weight of the polymer and between about 25% and 55% by weight of the dopant, based on the composition. In another embodiment, the doped polythiophene composition comprises between about 50% and 65% for the polythiophene and between about 35% and 50% of the dopant, based on the composition. Typically, the amount by weight of the polythiophene is greater than the amount by weight of the dopant. Typically, the dopant can be a silver salt, such as silver tetrakis(pentafluorophenyl)borate in an amount of about 0.25 to 0.5 m/ru, wherein m is the molar amount of silver salt and ru is the molar amount of polymer repeat unit.

The doped polythiophene is isolated according to methods known to those of ordinary skill in the art, such as, for example, by rotary evaporation of the solvent, to obtain a dry or substantially dry material, such as a powder. The amount of residual solvent can be, for example, 10 wt. % or less, or 5 wt. % or less, or 1 wt. % or less, based on the dry or substantially dry material. The dry or substantially dry powder can be redispersed or redissolved in one or more new solvents.

The hole-carrying film of the device according to the present disclosure comprises one or more metallic or metalloid nanoparticles.

As used herein, the term “nanoparticle” refers to a nanoscale particle, the number average diameter of which is typically less than or equal to 500 nm. The number average diameter may be determined using techniques and instrumentation known to those of ordinary skill in the art. For instance, transmission electron microscopy (TEM) may be used.

TEM may be used to characterize size and size distribution, among other properties, of the metalloid nanoparticles. Generally, TEM works by passing an electron beam through a thin sample to form an image of the area covered by the electron beam with magnification high enough to observe the lattice structure of a crystal. The measurement sample is prepared by evaporating a dispersion having a suitable concentration of nanoparticles on a specially-made mesh grid. The crystal quality of the nanoparticles can be measured by the electron diffraction pattern and the size and shape of the nanoparticles can be observed in the resulting micrograph image. Typically, the number of nanoparticles and projected two-dimensional area of every nanoparticle in the field-of-view of the image, or fields-of-view of multiple images of the same sample at different locations, are determined using image processing software, such as ImageJ (available from US National Institutes of Health). The projected two-dimensional area, A, of each nanoparticle measured is used to calculate its circular equivalent diameter, or area-equivalent diameter, x_{A}, which is defined as the diameter of a circle with the same area as the nanoparticle. The circular equivalent diameter is simply given by the equation

$${x}_{A} = \sqrt{\frac{4 A}{π}}$$

The arithmetic average of the circular equivalent diameters of all of the nanoparticles in the observed image is then calculated to arrive at the number average particle diameter, as used herein. A variety of TEM microscopes available, for instance, Jeol JEM-2100F Field Emission TEM and Jeol JEM 2100 LaB6 TEM (available from JEOL USA). It is understood that all TE microscopes function on similar principles and when operated according to standard procedures, the results are interchangeable.

There is no particular limitation to the size of the nanoparticles used in the hole-carrying film of the device described herein. However, it would be understood by the ordinarily-skilled artisan that the nanoparticles used in the hole-carrying film should have particle diameter not exceeding the thickness of the hole-carrying film. Typically, the number average particle diameter of the nanoparticles described herein is less than or equal to 500 nm; less than or equal to 250 nm; less than or equal to 100 nm; or less than or equal to 50 nm; or less than or equal to 25 nm. Typically, the nanoparticles have number average particle diameter from about 1 nm to about 100 nm, more typically from about 2 nm to about 30 nm.

The shape or geometry of the nanoparticles of the present disclosure can be characterized by number average aspect ratio. As used herein, the terminology “aspect ratio” means the ratio of the Feret's minimum length to the Feret's maximum length, or

$$\frac{{x}_{F min}}{{x}_{F max}} .$$

As used herein, the maximum Feret's diameter, x_{Fmax}, is defined as the furthest distance between any two parallel tangents on the two-dimensional projection of a particle in a TEM micrograph. Likewise, the minimum Feret's diameter, x_{Fmin}, is defined as the shortest distance between any two parallel tangents on the two-dimensional projection of a particle in a TEM micrograph. The aspect ratio of each particle in the field-of-view of a micrograph is calculated and the arithmetic average of the aspect ratios of all of the particles in the image is calculated to arrive at the number average aspect ratio. Generally, the number average aspect ratio of the nanoparticles described herein is from about 0.9 to about 1.1, typically about 1.

Metallic nanoparticles suitable for use according to the present disclosure may comprise a metal oxide, or mixed metal oxide, such as indium tin oxide (ITO). Metals include, for example, main group metals such as, for example, lead, tin, bismuth, and indium, and transition metals, for example, a transition metal selected from the group consisting of gold, silver, copper, nickel, cobalt, palladium, platinum, iridium, osmium, rhodium, ruthenium, rhenium, vanadium, chromium, manganese, niobium, molybdenum, tungsten, tantalum, titanium, zirconium, zinc, mercury, yttrium, iron and cadmium. Some non-limiting, specific examples of suitable metallic nanoparticles include, but are not limited to, nanoparticles comprising a transition metal oxide, such as zirconium oxide (ZrO₂), titanium dioxide (TiO₂), zinc oxide (ZnO), vanadium(V) oxide (V₂O₅), molybdenum trioxide (MoO₃), and tungsten trioxide (WO₃).

As used herein, the term “metalloid” refers to an element having chemical and/or physical properties intermediate of, or that are a mixture of, those of metals and nonmetals. Herein, the term “metalloid” refers to boron (B), silicon (Si), germanium (Ge), arsenic (As), antimony (Sb), and tellurium (Te).

Metalloid nanoparticles suitable for use according to the present disclosure may comprise boron (B), silicon (Si), germanium (Ge), arsenic (As), antimony (Sb), tellurium (Te), tin (Sn) and/or oxides thereof. Some non-limiting, specific examples of suitable metalloid nanoparticles include, but are not limited to, nanoparticles comprising B₂O₃, B₂O, SiO₂, SiO, GeO₂, GeO, As₂O₄, As₂O₃, As₂O₅, Sb₂O₃, TeO₂, and mixtures thereof.

In an embodiment, the one or more nanoparticles are metalloid nanoparticles.

In another embodiment, the metalloid nanoparticles comprise B₂O₃, B₂O, SiO₂, SiO, GeO₂, GeO, As₂O₄, As₂O₃, As₂O₅, SnO₂, SnO, Sb₂O₃, TeO₂, or mixtures thereof.

In an embodiment, the metalloid nanoparticles comprise SiO₂.

Suitable SiO₂ nanoparticles are available as dispersions in various solvents, such as, for example, methyl ethyl ketone, methyl isobutyl ketone, N,N-dimethylacetamide, ethylene glycol, isopropanol, methanol, ethylene glycol monopropyl ether, and propylene glycol monomethyl ether acetate, marketed as ORGANOSILICASOL™ by Nissan Chemical.

The one or more metallic or metalloid nanoparticles may comprise one or more organic capping groups. Such organic capping groups may be reactive or non-reactive. Reactive organic capping groups are organic capping groups capable of cross-linking, for example, in the presence of UV radiation or radical initiators.

In an embodiment, the nanoparticles comprise one or more organic capping groups.

The amount of the one or more metallic or metalloid nanoparticles used in the hole-carrying film of the device described herein can be controlled and measured as a weight percentage relative to the combined weight of the one or more metallic or metalloid nanoparticles and the doped or undoped polythiophene. In an embodiment, the amount of the one or more metallic or metalloid nanoparticles is from 1 wt. % to 98 wt. %, typically from about 2 wt. to about 95 wt. %, more typically from about 5 wt. % to about 90 wt. %, still more typically about 10 wt. % to about 90 wt. %, relative to the combined weight of the nanoparticles and the doped or undoped polythiophene. In an embodiment, the amount of the one or more metallic or metalloid nanoparticles is from about 20 wt. % to about 98 wt. %, typically from about 25 wt. to about 95 wt. %, relative to the combined weight of the nanoparticles and the doped or undoped polythiophene.

The nanoparticles in the hole-carrying film of the device according to the present disclosure are randomly distributed throughout the hole-carrying film.

The hole-carrying film of the device of the present disclosure may optionally further comprise one or more matrix compounds known to be useful in hole injection layers (HILs) or hole transport layers (HTLs).

The optional matrix compound can be a lower or higher molecular weight compound, and is different from the polythiophene described herein. The matrix compound can be, for example, a synthetic polymer that is different from the polythiophene. See, for example, US Patent Publication No. 2006/0175582 published Aug. 10, 2006. The synthetic polymer can comprise, for example, a carbon backbone. In some embodiments, the synthetic polymer has at least one polymer side group comprising an oxygen atom or a nitrogen atom. The synthetic polymer may be a Lewis base. Typically, the synthetic polymer comprises a carbon backbone and has a glass transition temperature of greater than 25° C. The synthetic polymer may also be a semi-crystalline or crystalline polymer that has a glass transition temperature equal to or lower than 25° C. and/or a melting point greater than 25° C. The synthetic polymer may comprise one or more acidic groups, for example, sulfonic acid groups.

In an embodiment, the synthetic polymer is a polymeric acid comprising one or more repeating units comprising at least one alkyl or alkoxy group which is substituted by at least one fluorine atom and at least one sulfonic acid (—SO₃H) moiety, wherein said alkyl or alkoxy group is optionally interrupted by at least one ether linkage (—O—) group.

In an embodiment, the polymeric acid comprises a repeating unit complying with formula (II) and a repeating unit complying with formula (III)

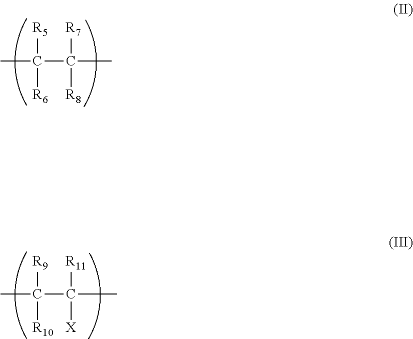

wherein each occurrence of R₅, R₆, R₇, R₈, R₉, R₁₀, and R₁₁ is, independently, H, halogen, fluoroalkyl, or perfluoroalkyl; and X is —[OC(RₕRᵢ)—C(RⱼRₖ)]_{q}—O—[CRₗRₘ]_{z}—SO₃ H, wherein each occurrence of Rₕ, Rᵢ, Rⱼ, Rₖ, Rₗ and Rₘ is, independently, H, halogen, fluoroalkyl, or perfluoroalkyl; q is 0 to 10; and z is 1-5.

In an embodiment, each occurrence of R₅, R₆, R₇, and R₈ is, independently, Cl or F. In an embodiment, each occurrence of R₅, R₇, and R₈ is F, and R₆ is Cl. In an embodiment, each occurrence of R₅, R₆, R₇, and R₈ is F.

In an embodiment, each occurrence of R₉, R₁₀, and R₁₁ is F.

In an embodiment, each occurrence of Rₕ, Rᵢ, Rⱼ, Rₖ, Rₗ and Rₘ is, independently, F, (C₁-C₈)fluoroalkyl, or (C₁-C₈)perfluoroalkyl.

In an embodiment, each occurrence of Rₗ and Rₘ is F; q is 0; and z is 2.

In an embodiment, each occurrence of R₅, R₇, and R₈ is F, and R₆ is Cl; and each occurrence of Rₗ and Rₘ is F; q is 0; and z is 2.

In an embodiment, each occurrence of R₅, R₆, R₇, and R₈ is F; and each occurrence of Rₗ and Rₘ is F; q is 0; and z is 2.

The ratio of the number of repeating units complying with formula (II) (“n”) to the number of the repeating units complying with formula (III) (“m”) is not particularly limited. The n:m ratio is typically from 9:1 to 1:9, more typically 8:2 to 2:8. In an embodiment, the n:m ratio is 9:1. In an embodiment, the n:m ratio is 8:2.

The polymeric acid suitable for use according to the present disclosure may be synthesized using methods known to those of ordinary skill in the art or obtained from commercially-available sources. For instance, the polymers comprising a repeating unit complying with formula (II) and a repeating unit complying with formula (III) may be made by co-polymerizing monomers represented by formula (IIa) with monomers represented by formula (IIIa)

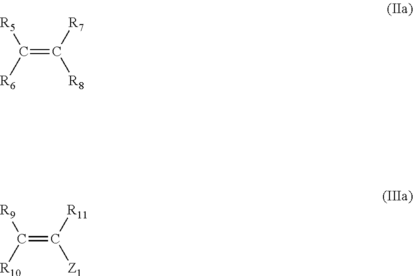

wherein Z₁ is —[OC(RₕRᵢ)—C(RⱼRₖ)]_{q}—O—[CRₗRₘ]_{z}—SO₂F, wherein Rₕ, Rᵢ, Rⱼ, Rₖ, Rₗ and Rₘ, q, and z are as defined herein, according to known polymerization methods, followed by conversion to sulfonic acid groups by hydrolysis of the sulfonyl fluoride groups.

For example, tetrafluoroethylene (TFE) or chlorotrifluoroethylene (CTFE) may be copolymerized with one or more fluorinated monomers comprising a precursor group for sulfonic acid, such as, for example, F₂C═CF—O—CF₂—CF₂—SO₂F; F₂C═CF—[O—CF₂—CR₁₂F—O]_{q}—CF₂—CF₂—SO₂F, wherein R₁₂ is F or CF₃ and q is 1 to 10; F₂C═CF—O—CF₂—CF₂—CF₂—SO₂F; and F₂C═CF—OCF₂—CF₂—CF₂—CF₂—SO₂F.

The equivalent weight of the polymeric acid is defined as the mass, in grams, of the polymeric acid per mole of acidic groups present in the polymeric acid. The equivalent weight of the polymeric acid is from about 400 to about 15,000 g polymer/mol acid, typically from about 500 to about 10,000 g polymer/mol acid, more typically from about 500 to 8,000 g polymer/mol acid, even more typically from about 500 to 2,000 g polymer/mol acid, still more typically from about 600 to about 1,700 g polymer/mol acid.

Such polymeric acids are, for instance, those marketed by E. I. DuPont under the trade name NAFION®, those marketed by Solvay Specialty Polymers under the trade name AQUIVION®, or those marketed by Asahi Glass Co. under the trade name FLEMION®.

In an embodiment, the synthetic polymer is a polyether sulfone comprising one or more repeating units comprising at least one sulfonic acid (—SO₃H) moiety.

In an embodiment, the polyether sulfone comprises a repeating unit complying with formula (IV)

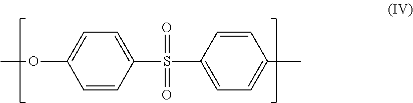

and a repeating unit selected from the group consisting of a repeating unit complying with formula (V) and a repeating unit complying with formula (VI)

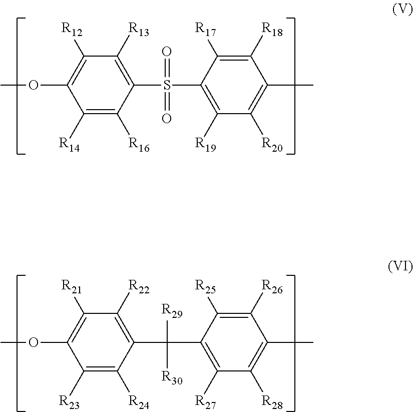

wherein R₁₂-R₂₀ are each, independently, H, halogen, alkyl, or SO₃H, provided that at least one of R₁₂-R₂₀ is SO₃H; and wherein R₂₁-R₂₈ are each, independently, H, halogen, alkyl, or SO₃H, provided that at least one of R₂₁-R₂₈ is SO₃H, and R₂₉ and R₃₀ are each H or alkyl.

In an embodiment, R₂₉ and R₃₀ are each alkyl. In an embodiment, R₂₉ and R₃₀ are each methyl.

In an embodiment, R₁₂-R₁₇, R₁₉, and R₂₀, are each H and R₁₈ is SO₃H.

In an embodiment, R₂₁-R₂₅, R₂₇, and R₂₈, are each H and R₂₆ is SO₃H.

In an embodiment, the polyether sulfone is represented by formula (VII)

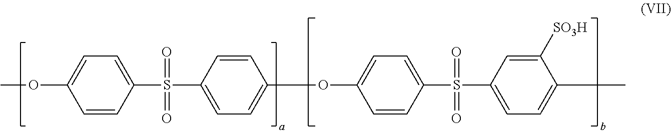

wherein a is from 0.7 to 0.9 and b is from 0.1 to 0.3.

The polyether sulfone may further comprise other repeating units, which may or may not be sulfonated.

For example, the polyether sulfone may comprise a repeating unit of formula (VIII)

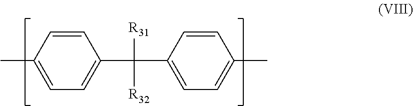

wherein R₃₁ and R₃₂ are each, independently, H or alkyl.

Any two or more repeating units described herein may together form a repeating unit and the polyether sulfone may comprise such a repeating unit. For example, the repeating unit complying with formula (IV) may be combined with a repeating unit complying with formula (VI) to give a repeating unit complying with formula (IX)

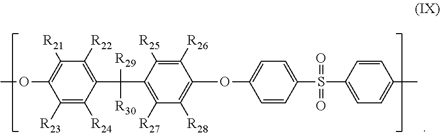

Analogously, for example, the repeating unit complying with formula (IV) may be combined with a repeating unit complying with formula (VIII) to give a repeating unit complying with formula (X)

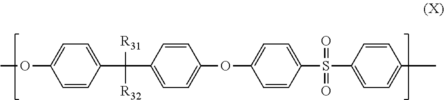

In an embodiment, the polyether sulfone is represented by formula (XI)

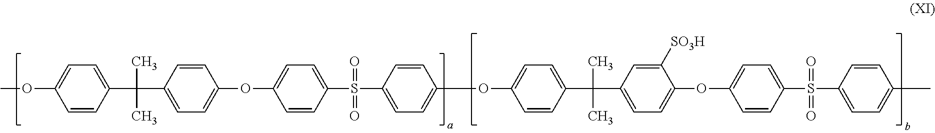

wherein a is from 0.7 to 0.9 and b is from 0.1 to 0.3.

Polyether sulfones comprising one or more repeating units comprising at least one sulfonic acid (—SO₃H) moiety are commercially-available, for example, sulfonated polyether sulfones marketed as S-PES by Konishi Chemical Ind. Co., Ltd.

The optional matrix compound can be a planarizing agent. A matrix compound or a planarizing agent may be comprised of, for example, a polymer or oligomer such as an organic polymer, such as poly(styrene) or poly(styrene) derivatives; poly(vinyl acetate) or derivatives thereof; poly(ethylene glycol) or derivatives thereof; poly(ethylene-co-vinyl acetate); poly(pyrrolidone) or derivatives thereof (e.g., poly(1-vinylpyrrolidone-co-vinyl acetate)); poly(vinyl pyridine) or derivatives thereof; poly(methyl methacrylate) or derivatives thereof; poly(butyl acrylate); poly(aryl ether ketones); poly(aryl sulfones); poly(esters) or derivatives thereof; or combinations thereof.

In an embodiment, the matrix compound is poly(styrene) or poly(styrene) derivative.

In an embodiment, the matrix compound is poly(4-hydroxystyrene).

The optional matrix compound or planarizing agent may be comprised of, for example, at least one semiconducting matrix component. The semiconducting matrix component is different from the polythiophene described herein. The semiconducting matrix component can be a semiconducting small molecule or a semiconducting polymer that is typically comprised of repeat units comprising hole carrying units in the main-chain and/or in a side-chain. The semiconducting matrix component may be in the neutral form or may be doped, and is typically soluble and/or dispersible in organic solvents, such as toluene, chloroform, acetonitrile, cyclohexanone, anisole, chlorobenzene, o-dichlorobenzene, ethyl benzoate and mixtures thereof.

The amount of the optional matrix compound can be controlled and measured as a weight percentage relative to the amount of the doped or undoped polythiophene. In an embodiment, the amount of the optional matrix compound is from 0 to 99.5 wt. %, typically from about 10 wt. to about 98 wt. %, more typically from about 20 wt. % to about 95 wt. %, still more typically about 25 wt. % to about 45 wt. %, relative to the amount of the doped or undoped polythiophene. In the embodiment with 0 wt. %, the hole-carrying film is free of matrix compound.

The hole-carrying film or the device described in the present disclosure may be made according to any method known to those of ordinary skill in the art including, for example, solution processing. Typically, a non-aqueous ink composition comprising the polythiophene, the one or more metallic or metalloid nanoparticles, and a liquid carrier, is coated on a substrate and then annealed. The film prepared according to the processes described herein may be an HIL and/or HTL layer in the device.

The ink compositions of the present disclosure are non-aqueous. As used herein, “non-aqueous” means that the total amount of water present in the ink compositions of the present disclosure is from 0 to 5% wt., with respect to the total amount of the liquid carrier. Typically, the total amount of water in the ink composition is from 0 to 2% wt, more typically from 0 to 1% wt, even more typically from 0 to 0.5% wt, with respect to the total amount of the liquid carrier. In an embodiment, the ink composition of the present disclosure is free of any water.

The non-aqueous ink compositions of the present disclosure may optionally comprise one or more amine compounds. Suitable amine compounds for use in the non-aqueous ink compositions of the present disclosure include, but are not limited to, ethanolamines and alkylamines.

Examples of suitable ethanolamines include dimethylethanol amine [(CH₃)₂NCH₂CH₂OH], triethanol amine [N(CH₂CH₂OH)₃], and N-tert-butyldiethanol amine [t-C₄H₉N(CH₂CH₂OH)₂].

Alkylamines include primary, secondary, and tertiary alkylamines. Examples of primary alkylamines include, for example, ethylamine [C₂H₅NH₂], n-butylamine [C₄H₉ NH₂], t-butylamine [C₄H₉NH₂], n-hexylamine[C₆H₁₃NH₂], n-decylamine[C₁₀H₂₁NH₂], and ethylenediamine [H₂NCH₂CH₂NH₂]. Secondary alkylamines include, for example, diethylamine [(C₂H₅)₂NH], di(n-propylamine) [(n-C₃H₉)₂NH], di(iso-propylamine) [(i-C₃H₉)₂NH], and dimethyl ethylenediamine [CH₃NHCH₂CH₂NHCH₃]. Tertiary alkylamines include, for example, trimethylamine [(CH₃)₃N], triethylamine [(C₂H₅)₃N], tri(n-butyl)amine [(C₄H₉)₃N], and tetramethyl ethylenediamine [(CH₃)₂NCH₂CH₂N(CH₃)_{2]}.

In an embodiment, the amine compound is a tertiary alkylamine. In an embodiment, the amine compound is triethylamine.

The amount of the amine compound can be controlled and measured as a weight percentage relative to the total amount of the ink composition. In an embodiment, the amount of the amine compound is at least 0.01 wt. %, at least 0.10 wt. %, at least 1.00 wt. %, at least 1.50 wt. %, or at least 2.00 wt. %, with respect to the total amount of the ink composition. In an embodiment, the amount of the amine compound is from about 0.01 to about 2.00 wt. %, typically from about 0.05% wt. to about 1.50 wt. %, more typically from about 0.1 wt. % to about 1.0 wt. %, with respect to the total amount of the ink composition.

The liquid carrier used in the ink composition according to the present disclosure comprises one or more organic solvents. In an embodiment, the ink composition consists essentially of or consists of one or more organic solvents. The liquid carrier may be an organic solvent or solvent blend comprising two or more organic solvents adapted for use and processing with other layers in a device such as the anode or light emitting layer.

Organic solvents suitable for use in the liquid carrier include, but are not limited to, aliphatic and aromatic ketones, organosulfur solvents, such as dimethyl sulfoxide (DMSO) and 2,3,4,5-tetrahydrothiophene-1,1-dioxide (tetramethylene sulfone; Sulfolane), tetrahydrofuran (THF), tetrahydropyran (THP), tetramethyl urea (TMU), N,N′-dimethylpropyleneurea, alkylated benzenes, such as xylene and isomers thereof, halogenated benzenes, N-methylpyrrolidinone (NMP), dimethylformamide (DMF), dimethylacetamide (DMAc), dichloromethane, acetonitrile, dioxanes, ethyl acetate, ethyl benzoate, methyl benzoate, dimethyl carbonate, ethylene carbonate, propylene carbonate, 3-methoxypropionitrile, 3-ethoxypropionitrile, or combinations thereof.

Aliphatic and aromatic ketones include, but are not limited to, acetone, acetonyl acetone, methyl ethyl ketone (MEK), methyl isobutyl ketone, methyl isobutenyl ketone, 2-hexanone, 2-pentanone, acetophenone, ethyl phenyl ketone, cyclohexanone, and cyclopentanone. In some embodiments, ketones with protons on the carbon located alpha to the ketone are avoided, such as cyclohexanone, methyl ethyl ketone, and acetone.

Other organic solvents might also be considered that solubilize, completely or partially, the polythiophene polymer or that swell the polythiophene polymer. Such other solvents may be included in the liquid carrier in varying quantities to modify ink properties such as wetting, viscosity, morphology control. The liquid carrier may further comprise one or more organic solvents that act as non-solvents for the polythiophene polymer.

Other organic solvents suitable for use according to the present disclosure include ethers such as anisole, ethoxybenzene, dimethoxy benzenes and glycol ethers, such as, ethylene glycol diethers, such as 1,2-dimethoxyethane, 1,2-diethoxyethane, and 1,2-dibutoxyethane; diethylene glycol diethers such as diethylene glycol dimethyl ether, and diethylene glycol diethyl ether; propylene glycol diethers such as propylene glycol dimethyl ether, propylene glycol diethyl ether, and propylene glycol dibutyl ether; dipropylene glycol diethers, such as dipropylene glycol dimethyl ether, dipropylene glycol diethyl ether, and dipropylene glycol dibutyl ether; as well as higher analogues (i.e., tri- and tetra-analogues) of the ethylene glycol and propylene glycol ethers mentioned herein, such as triethylene glycol dimethyl ether, triethylene glycol butyl methyl ether and tetraethylene glycol dimethyl ether.

Still other solvents can be considered, such as ethylene glycol monoether acetates and propylene glycol monoether acetates (glycol ester ethers), wherein the ether can be selected, for example, from methyl, ethyl, n-propyl, iso-propyl, n-butyl, sec-butyl, tertbutyl, and cyclohexyl. Higher glycol ether analogues of the above list, such as di-, triand tetra-, are also included.

Examples include, but are not limited to, propylene glycol methyl ether acetate, 2-ethoxyethyl acetate, 2-butoxyethyl acetate, ethylene glycol monomethyl ether acetate and diethylene glycol monomethyl ether acetate.

Still other solvents can be considered, such as ethylene glycol diacetate (glycol diesters). Higher glycol ether analogues, such as di-, tri- and tetra-, are also included.

Examples include, but are not limited to, ethylene glycol diacetate, triethylene glycol diacetate and propylene glycol diacetate.

Alcohols may also be considered for use in the liquid carrier, such as, for example, methanol, ethanol, trifluoroethanol, n-propanol, isopropanol, n-butanol, t-butanol, and and alkylene glycol monoethers (glycol monoethers). Examples of suitable glycol monoethers include, but are not limited to, ethylene glycol monopropyl ether, ethylene glycol monohexyl ether (hexyl Cellosolve), propylene glycol monobutyl ether (Dowanol PnB), diethylene glycol monoethyl ether (ethyl Carbitol), dipropylene glycol n-butyl ether (Dowanol DPnB), diethylene glycol monophenyl ether (phenyl Carbitol), ethylene glycol monobutyl ether (butyl Cellosolve), diethylene glycol monobutyl ether (butyl Carbitol), dipropylene glycol monomethyl ether (Dowanol DPM), diisobutyl carbinol, 2-ethylhexyl alcohol, methyl isobutyl carbinol, ethylene glycol monophenyl ether (Dowanol Eph), propylene glycol monopropyl ether (Dowanol PnP), propylene glycol monophenyl ether (Dowanol PPh), diethylene glycol monopropyl ether (propyl Carbitol), diethylene glycol monohexyl ether (hexyl Carbitol), 2-ethylhexyl carbitol, dipropylene glycol monopropyl ether (Dowanol DPnP), tripropylene glycol monomethyl ether (Dowanol TPM), diethylene glycol monomethyl ether (methyl Carbitol), and tripropylene glycol monobutyl ether (Dowanol TPnB).

As disclosed herein, the organic solvents disclosed herein can be used in varying proportions in the liquid carrier, for example, to improve the ink characteristics such as substrate wettability, ease of solvent removal, viscosity, surface tension, and jettability.

In some embodiments, the use of aprotic non-polar solvents can provide the additional benefit of increased life-times of devices with emitter technologies which are sensitive to protons, such as, for example, PHOLEDs.

In an embodiment, the liquid carrier comprises dimethyl sulfoxide, ethylene glycol (glycols), tetramethyl urea, or a mixture thereof.

Examples of suitable glycols include, but are not limited to, ethylene glycol, diethylene glycol, dipropylene glycol, polypropylene glycol, propylene glycol and triethylene glycol.

The above-mentioned glycol ethers, glycol ester ethers, glycol diesters, glycol monoethers and glycols are collectively referred to as “glycol-based solvents”.

In an embodiment, the liquid carrier consists of (A) one or more glycol-based solvents.

In an embodiment, the liquid carrier comprises (A) one or more glycol-based solvents and (B) one or more organic solvents other than the glycol-based solvents.

In an embodiment, the liquid carrier comprises one or more glycol-based solvents and (B′) one or more organic solvents other than the glycol-based solvents, tetramethylurea and dimethylsulfoxide.

As examples of preferred glycol-based solvents (A), there can be mentioned glycol ethers, glycol monoethers and glycols which can be used in combination.

Examples include, but are not limited to, a mixture of a glycol ether and a glycol.

As specific examples, there can be mentioned specific examples of the above-mentioned glycol ethers and glycols. Examples of preferred glycol ethers include triethylene glycol dimethyl ether and triethylene glycol butyl methyl ether. Examples of preferred glycols include ethylene glycol and diethylene glycol.

As examples of the above-mentioned organic solvents (B), there can be mentioned nitriles, alcohols, aromatic ethers and aromatic hydrocarbons.

Examples include, but are not limited to, methoxypropionitrile and ethoxypropionitrile as the nitriles; benzylalcohol and 2-(benzyloxy)ethanol as the alcohols; methylanisole, dimethylanisole, ethylanisole, butyl phenyl ether, butylanisole, pentylanisole, hexylanisole, heptylanisole, octylanisole and phenoxytoluene as the aromatic ethers; and pentylbenzene, hexylbenzene, heptylbenzene, octylbenzene, nonylbenzene, cyclohexylbenzene and tetralin as the aromatic hydrocarbons.

It is preferred that the the proportion by weight (wtA) of the above-mentioned glycol-based solvent (A) and the proportion by weight (wtB) of the above-mentioned organic solvent (B) satisfy the relationship represented by the following formula (1-1), more preferably the following formula (1-2), most preferably the following formula (1-3).

0.05≤wtB/(wtA+wtB)≤0.50 (1-1)

0.10≤wtB/(wtA+wtB)≤0.40 (1-2)

0.15≤wtB/(wtA+wtB)≤0.30 (1-3)

When the composition of the present invention contains 2 or more glycol-based solvent (A), wtA represents the total proportion by weight of the glycol-based solvents (A) and, when the composition of the present invention contains 2 or more organic solvent (B), wtB represents the total proportion by weight of the organic solvent (B).

It is preferred that the the proportion by weight (wtA) of the above-mentioned glycol-based solvent (A) and the proportion by weight (wtB′) of the above-mentioned organic solvent (B′) satisfy the relationship represented by the following formula (1-1), more preferably the following formula (1-2), most preferably the following formula (1-3).

0.05≤wtB/(wtA+wtB′)≤0.50 (1-1)

0.10≤wtB/(wtA+wtB′)≤0.40 (1-2)

0.15≤wtB/(wtA+wtB′)≤0.30 (1-3)

When the composition of the present invention contains 2 or more glycol-based solvent (A), wtA represents the total proportion by weight of the glycol-based solvents (A) and, when the composition of the present invention contains 2 or more organic solvent (B′), wtB′ represents the total proportion by weight of the organic solvent (B′).

The amount of liquid carrier in the ink composition according to the present disclosure is from about 50 wt. % to about 99 wt. %, typically from about 75 wt. % to about 98 wt. %, still more typically from about 90 wt. % to about 95 wt. %, with respect to the total amount of ink composition.

The total solids content (% TS) in the ink composition according to the present disclosure is from about 0.1 wt. % to about 50 wt. %, typically from about 0.3 wt. % to about 40 wt. %, more typically from about 0.5 wt. % to about 15 wt. %, still more typically from about 1 wt. % to about 5 wt. %, with respect to the total amount of ink composition.

The non-aqueous ink compositions described herein may be prepared according to any suitable method known to the ordinarily-skilled artisan. For example, in one method, an initial aqueous mixture is prepared by mixing an aqueous dispersion of the polythiophene described herein with an aqueous dispersion of polymeric acid, if desired, another matrix compound, if desired, and additional solvent. The solvents, including water, in the mixture are then removed, typically by evaporation. The resulting dry product is then dissolved or dispersed in one or more organic solvents, such as dimethyl sulfoxide, and filtered under pressure to yield a non-aqueous mixture. An amine compound may optionally be added to such non-aqueous mixture. The non-aqueous mixture is then mixed with a non-aqueous dispersion of the nanoparticles to yield the final non-aqueous ink composition.

In another method, the non-aqueous ink compositions described herein may be prepared from stock solutions. For example, a stock solution of the polythiophene described herein can be prepared by isolating the polythiophene in dry form from an aqueous dispersion, typically by evaporation. The dried polythiophene is then combined with one or more organic solvents and, optionally, an amine compound. If desired, a stock solution of the polymeric acid described herein can be prepared by isolating the polymeric acid in dry form from an aqueous dispersion, typically by evaporation. The dried polymeric acid is then combined with one or more organic solvents. Stock solutions of other optional matrix materials can be made analogously. Stock solutions of the metalloid nanoparticles can be made, for example, by diluting commercially-available dispersions with one or more organic solvents, which may be the same or different from the solvent or solvents contained in the commercial dispersion. Desired amounts of each stock solution are then combined to form the non-aqueous ink compositions of the present disclosure.

Still in another method, the non-aqueous ink compositions described herein may be prepared by isolating the individual components in dry form as described herein, but instead of preparing stock solutions, the components in dry form are combined and then dissolved in one or more organic solvents to provide the NQ ink composition.

The coating of the ink composition on a substrate can be carried out by methods known in the art including, for example, spin casting, spin coating, dip casting, dip coating, slot-dye coating, ink jet printing, gravure coating, doctor blading, and any other methods known in the art for fabrication of, for example, organic electronic devices.

The substrate can be flexible or rigid, organic or inorganic. Suitable substrate compounds include, for example, glass, including, for example, display glass, ceramic, metal, and plastic films.

As used herein, the term “annealing” refers to any general process for forming a hardened layer, typically a film, on a substrate coated with the non-aqueous ink composition of the present disclosure. General annealing processes are known to those of ordinary skill in the art. Typically, the solvent is removed from the substrate coated with the non-aqueous ink composition. The removal of solvent may be achieved, for example, by subjecting the coated substrate to pressure less than atmospheric pressure, and/or by heating the coating layered on the substrate to a certain temperature (annealing temperature), maintaining the temperature for a certain period of time (annealing time), and then allowing the resulting layer, typically a film, to slowly cool to room temperature.

The step of annealing can be carried out by heating the substrate coated with the ink composition using any method known to those of ordinary skill in the art, for example, by heating in an oven or on a hot plate. Annealing can be carried out under an inert environment, for example, nitrogen atmosphere or noble gas atmosphere, such as, for example, argon gas. Annealing may be carried out in air atmosphere.

In an embodiment, the annealing temperature is from about 25° C. to about 350° C., typically from about 150° C. to about 325° C., more typically from about 200° C. to about 300° C., still more typically from about 230° C. to about 300° C.

The annealing time is the time for which the annealing temperature is maintained. The annealing time is from about 3 to about 40 minutes, typically from about 15 to about 30 minutes.

In an embodiment, the annealing temperature is from about 25° C. to about 350° C., typically from about 150° C. to about 325° C., more typically from about 200° C. to about 300° C., still more typically from about 250° C. to about 300° C., and the annealing time is from about 3 to about 40 minutes, typically for about 15 to about 30 minutes.

Transmission of visible light is important, and good transmission (low absorption) at higher film thicknesses is particularly important. For example, the film made according to the process of the present disclosure can exhibit a transmittance (typically, with a substrate) of at least about 85%, typically at least about 90%, of light having a wavelength of about 380-800 nm. In an embodiment, the transmittance is at least about 90%.

In one embodiment, the film made according to the process of the present disclosure has a thickness of from about 5 nm to about 500 nm, typically from about 5 nm to about 150 nm, more typically from about 50 nm to 120 nm.

In an embodiment, the film made according to the process of the present disclosure exhibits a transmittance of at least about 90% and has a thickness of from about 5 nm to about 500 nm, typically from about 5 nm to about 150 nm, more typically from about 50 nm to 120 nm. In an embodiment, the film made according to the process of the present disclosure exhibits a transmittance (% T) of at least about 90% and has a thickness of from about 50 nm to 120 nm.

The films made according to the processes of the present disclosure may be made on a substrate optionally containing an electrode or additional layers used to improve electronic properties of a final device. The resulting films may be intractable to one or more organic solvents, which can be the solvent or solvents used as liquid carrier in the ink for subsequently coated or deposited layers during fabrication of a device. The films may be intractable to, for example, toluene, which can be the solvent in the ink for subsequently coated or deposited layers during fabrication of a device.

Methods are known in the art and can be used to fabricate organic electronic devices including, for example, OLED and OPV devices. Methods known in the art can be used to measure brightness, efficiency, and lifetimes. Organic light emitting diodes (OLED) are described, for example, in U.S. Pat. Nos. 4,356,429 and 4,539,507 (Kodak). Conducting polymers which emit light are described, for example, in U.S. Pat. Nos. 5,247,190 and 5,401,827 (Cambridge Display Technologies). Device architecture, physical principles, solution processing, multilayering, blends, and compounds synthesis and formulation are described in Kraft et al., “Electroluminescent Conjugated Polymers-Seeing Polymers in a New Light,” Angew. Chem. Int. Ed., 1998, 37, 402-428, which is hereby incorporated by reference in its entirety.

Light emitters known in the art and commercially available can be used including various conducting polymers as well as organic molecules, such as compounds available from Sumation, Merck Yellow, Merck Blue, American Dye Sources (ADS), Kodak (e.g., A1Q3 and the like), and even Aldrich, such as BEHP-PPV. Examples of such organic electroluminescent compounds include:

(i) poly(p-phenylene vinylene) and its derivatives substituted at various positions on the phenylene moiety;

(ii) poly(p-phenylene vinylene) and its derivatives substituted at various positions on the vinylene moiety;

(iii) poly(p-phenylene vinylene) and its derivatives substituted at various positions on the phenylene moiety and also substituted at various positions on the vinylene moiety;

(iv) poly(arylene vinylene), where the arylene may be such moieties as naphthalene, anthracene, furylene, thienylene, oxadiazole, and the like;

(v) derivatives of poly(arylene vinylene), where the arylene may be as in (iv) above, and additionally have substituents at various positions on the arylene;

(vi) derivatives of poly(arylene vinylene), where the arylene may be as in (iv) above, and additionally have substituents at various positions on the vinylene;

(vii) derivatives of poly(arylene vinylene), where the arylene may be as in (iv) above, and additionally have substituents at various positions on the arylene and substituents at various positions on the vinylene;

(viii) co-polymers of arylene vinylene oligomers, such as those in (iv), (v), (vi), and (vii) with non-conjugated oligomers; and

(ix) poly(p-phenylene) and its derivatives substituted at various positions on the phenylene moiety, including ladder polymer derivatives such as poly(9,9-dialkyl fluorene) and the like;

(x) poly(arylenes) where the arylene may be such moieties as naphthalene, anthracene, furylene, thienylene, oxadiazole, and the like; and their derivatives substituted at various positions on the arylene moiety;

(xi) co-polymers of oligoarylenes, such as those in (x) with non-conjugated oligomers;

(xii) polyquinoline and its derivatives;

(xiii) co-polymers of polyquinoline with p-phenylene substituted on the phenylene with, for example, alkyl or alkoxy groups to provide solubility; and

(xiv) rigid rod polymers, such as poly(p-phenylene-2,6-benzobisthiazole), poly(p-phenylene-2,6-benzobisoxazole), poly(p-phenylene-2,6-benzimidazole), and their derivatives;

(xv) polyfluorene polymers and co-polymers with polyfluorene units.

Preferred organic emissive polymers include SUMATION Light Emitting Polymers (“LEPs”) that emit green, red, blue, or white light or their families, copolymers, derivatives, or mixtures thereof; the SUMATION LEPs are available from Sumation KK. Other polymers include polyspirofluorene-like polymers available from Covion Organic Semiconductors GmbH, Frankfurt, Germany (now owned by Merck®).

Alternatively, rather than polymers, small organic molecules that emit by fluorescence or by phosphorescence can serve as the organic electroluminescent layer. Examples of small-molecule organic electroluminescent compounds include: (i) tris(8-hydroxyquinolinato) aluminum (Alq); (ii) 1,3-bis(N,N-dimethylaminophenyl)-1,3,4-oxidazole (OXD-8); (iii) -oxo-bis(2-methyl-8-quinolinato)aluminum; (iv) bis(2-methyl-8-hydroxyquinolinato) aluminum; (v) bis(hydroxybenzoquinolinato) beryllium (BeQ₂); (vi) bis(diphenylvinyl)biphenylene (DPVBI); and (vii) arylamine-substituted distyrylarylene (DSA amine).

Such polymer and small-molecule compounds are well known in the art and are described in, for example, U.S. Pat. No. 5,047,687.

The devices can be fabricated in many cases using multilayered structures which can be prepared by, for example, solution or vacuum processing, as well as printing and patterning processes. In particular, use of the embodiments described herein for hole injection layers (HILs), wherein the composition is formulated for use as a hole injection layer, can be carried out effectively.

Examples of HIL in devices include:

1) Hole injection in OLEDs including PLEDs and SMOLEDs; for example, for HIL in PLED, all classes of conjugated polymeric emitters where the conjugation involves carbon or silicon atoms can be used. For HIL in SMOLED, the following are examples: SMOLED containing fluorescent emitters; SMOLED containing phosphorescent emitters; SMOLEDs comprising one or more organic layers in addition to the HIL layer; and SMOLEDs where the small molecule layer is processed from solution or aerosol spray or any other processing methodology. In addition, other examples include HIL in dendrimer or oligomeric organic semiconductor based OLEDs; HIL in ambipolar light emitting FET's where the HIL is used to modify charge injection or as an electrode;

2) Hole extraction layer in OPV;

3) Channel material in transistors;

4) Channel material in circuits comprising a combination of transistors, such as logic gates;

5) Electrode material in transistors;

6) Gate layer in a capacitor;

7) Chemical sensor where modification of doping level is achieved due to association of the species to be sensed with the conductive polymer;

8) Electrode or electrolyte material in batteries.

A variety of photoactive layers can be used in OPV devices. Photovoltaic devices can be prepared with photoactive layers comprising fullerene derivatives mixed with, for example, conducting polymers as described in, for example, U.S. Pat. Nos. 5,454,880; 6,812,399; and 6,933,436. Photoactive layers may comprise blends of conducting polymers, blends of conducting polymers and semiconducting nanoparticles, and bilayers of small molecules such as pthalocyanines, fullerenes, and porphyrins.

Common electrode compounds and substrates, as well as encapsulating compounds can be used.

In one embodiment, the cathode comprises Au, Ca, Al, Ag, or combinations thereof. In one embodiment, the anode comprises indium tin oxide. In one embodiment, the light emission layer comprises at least one organic compound.

Interfacial modification layers, such as, for example, interlayers, and optical spacer layers may be used.

Electron transport layers can be used.

The present disclosure also relates to a method of making a device described herein.

In an embodiment, the method of making a device comprises: providing a substrate; layering a transparent conductor, such as, for example, indium tin oxide, on the substrate; providing the ink composition described herein; layering the ink composition on the transparent conductor to form a hole injection layer or hole transport layer; layering an active layer on the hole injection layer or hole transport layer (HTL); and layering a cathode on the active layer.

As described herein, the substrate can be flexible or rigid, organic or inorganic. Suitable substrate compounds include, for example, glass, ceramic, metal, and plastic films.

In another embodiment, a method of making a device comprises applying the ink composition as described herein as part of an HIL or HTL layer in an OLED, a photovoltaic device, an ESD, a SMOLED, a PLED, a sensor, a supercapacitor, a cation transducer, a drug release device, an electrochromic device, a transistor, a field effect transistor, an electrode modifier, an electrode modifier for an organic field transistor, an actuator, or a transparent electrode.

The layering of the ink composition to form the HIL or HTL layer can be carried out by methods known in the art including, for example, spin casting, spin coating, dip casting, dip coating, slot-dye coating, ink jet printing, gravure coating, doctor blading, and any other methods known in the art for fabrication of, for example, organic electronic devices.

In one embodiment, the HIL layer is thermally annealed. In one embodiment, the HIL layer is thermally annealed at temperature of about 25° C. to about 350° C., typically 150° C. to about 325° C. In one embodiment, the HIL layer is thermally annealed at temperature of of about 25° C. to about 350° C., typically 150° C. to about 325° C., for about 3 to about 40 minutes, typically for about 15 to about 30 minutes.

In accordance with the present disclosure, an HIL or HTL can be prepared that can exhibit a transmittance (typically, with a substrate) of at least about 85%, typically at least about 90%, of light having a wavelength of about 380-800 nm. In an embodiment, the transmittance is at least about 90%.

In one embodiment, the HIL layer has a thickness of from about 5 nm to about 500 nm, typically from about 5 nm to about 150 nm, more typically from about 50 nm to 120 nm.

In an embodiment, the HIL layer exhibits a transmittance of at least about 90% and has a thickness of from about 5 nm to about 500 nm, typically from about 5 nm to about 150 nm, more typically from about 50 nm to 120 nm. In an embodiment, the HIL layer exhibits a transmittance (% T) of at least about 90% and has a thickness of from about 50 nm to 120 nm.

The present disclosure also relates to the use of one or more nanoparticles to increase the internal light outcoupling in an organic light emitting device comprising a hole-carrying film described herein, wherein the one or more nanoparticles are metallic or metalloid nanoparticles described herein.

Emissive materials of organic electronic devices, such as OLEDs, generally have a refractive index greater than 1.7, which is substantially higher than that of most of the supporting substrates, which are usually around 1.5. As light propagates from a higher index medium to a lower index medium, total internal reflection (TIR) occurs for light beams travelling in large oblique angles relative to the interface, according to Snell's law. In a typical OLED device, TIR occurs between organic layers (refractive index around 1.7) and the substrate (refractive index around 1.5); and between the substrate (refractive index around 1.5) and air (refractive index 1.0). In many cases, a large portion of light originating in an emissive layer within an OLED does not escape the device due to TIR at the air interface, edge emission, dissipation within the emissive or other layers, waveguide effects within the emissive layer or other layers of the device (i.e., transporting layers, injection layers, etc.), and other effects. Light generated and/or emitted by an OLED may be described as being in various modes, such as “air mode” (the light will be emitted from a viewing surface of the device, such as through the substrate) or “waveguide mode” (the light is trapped within the device due to waveguide effects). Specific modes may be described with respect to the layer or layers within which the light is trapped, such as “organic mode” (the light is trapped within one or more of the organic layers), “electrode mode” (trapped within an electrode), and “substrate mode” or “glass mode” (trapped within the substrate). These effects result in light trapping in the device and further reduce light extraction efficiency.

The use of one or more nanoparticles in an organic light emitting device comprising a hole-carrying film described herein, wherein the one or more nanoparticles are metallic or metalloid nanoparticles described herein, increases internal light outcoupling leading to increased light extraction efficiency when compared to organic light emitting devices not having such nanoparticles. Increases in internal light outcoupling may be shown by increases in external quantum efficiency (% EQE) when comparing organic light emitting devices having metallic or metalloid nanoparticles as described herein and organic light emitting devices not having such nanoparticles.

The present disclosure also relates to the use of one or more nanoparticles to enhance the color saturation, i.e., the saturation of the color of the emitted light, of an organic light emitting device comprising a hole-carrying film described herein, wherein the one or more nanoparticles are metallic or metalloid nanoparticles described herein. Color saturation may be shown by how close the CIE (Commission Internationale de l'Eclairage) x and y coordinates of the measured color of an organic light emitting device is to the CIE x and y coordinates of the intended, typically pure, color. The closer the CIE x and y coordinates of the measured color of an organic light emitting device is to the CIE x and y coordinates of the intended, typically pure, color, the more saturated the color is. Enhanced color saturation is observed as a deeper color in the organic light emitting devices having metallic or metalloid nanoparticles when compared to organic light emitting devices not having such nanoparticles.

Further, the present disclosure relates the use of one or more nanoparticles to improve color stability of an organic light emitting device comprising a hole-carrying film described herein, wherein the one or more nanoparticles are metallic or metalloid nanoparticles described herein.

Strong changes in spectrum and perceived color with viewing angle is a common problem in organic light emitting devices. As used herein, color stability refers to the tendency of the spectrum and perceived color to change with viewing angle. The less the spectrum and perceived color change as the viewing angle is varied, the more stable the color is. Color stability may be characterized by plotting CIE x and y coordinates as a function of observation angle for a given organic light emitting device.

The inks, methods and processes, films, and devices according to the present disclosure are further illustrated by the following non-limiting examples.

### EXAMPLES

The components used in the following examples are summarized in the following Table 1.

TABLE 1
Summary of components

| | |
|---|---|
| S-poly(3- | Sulfonated poly(3-MEET) |
| MEET) | |
| TFE-VEFS 1 | TFE/perfluoro-2-(vinyloxy)ethane-1-sulfonic acid |
| | copolymer having equivalent weight of 676 g |
| | polymer/mol acid (available from Solvay as AQUIVION ® |
| | D66-20BS); n:m = 8:2 |
| PHOST | Poly(4-hydroxystyrene) |
| TEA | Trimethylamine |
| PGME | Propylene glycol methyl ether (available from Dow |
| | Chemical Co. as DOWANOL ™ PM) |
| EG-ST | 20-21 wt % silica dispersion in ethylene glycol |
| | (ORGANOSILICASOL ™ EG-ST, available from Nissan |
| | Chemical) |
| EG | Ethylene glycol |

### Example 1. Preparation of Inventive NQ Inks

An inventive non-aqueous (NQ) ink compositions of the present invention were prepared according to methods described herein.

Inventive NQ ink 1 was prepared from stock solutions of components.

Stock Solution #1 Preparation

Rotary evaporation was used to isolate the solid components of an aqueous dispersion of S-poly(3-MEET). The dried solids were used to prepare a stock solution of S-poly(3-MEET) at 0.75% solids in DMSO with TEA. The solid S-poly(3-MEET) was dispersed in a sufficient amount of DMSO (assuming 100% of S-poly(3-MEET)). TEA was added at 0.25% by wt of total mixture. The dispersion was filtered under high pressure.

Stock Solution #2 Preparation

Rotary evaporation was used to isolate the solid components of an aqueous dispersion of TFE-VEFS 1 copolymer. The dried solids were used to prepare a stock solution at 3.0% solids in DMSO. The solution was made by combining 0.3 g of dried TFE-VEFS 1 copolymer with 9.70 g of DMSO. The mixture was mechanically stirred for 1 hour at room temperature.

Stock Solution #3 Preparation

A stock solution of PHOST at 8.0% solids was prepared by combining 4.88 g of PHOST with 56.12 g of DMSO. The solution was mechanically stirred for 1 hour at room temperature.

Stock Solution #4 Preparation

A stock solution of silica nanoparticles was prepared at 10.0% solids by combining 9.38 g of commercially-available 20-21 wt % silica dispersion in ethylene glycol (marketed as ORGANOSILICASOL™ EG-ST by Nissan Chemical) with 9.38 g of DMSO. The solution was mechanically stirred for 1 hour at room temperature.

NQ Ink 1 Preparation

The NQ ink 1 was prepared by stock solution #2 to stock solution #1, followed by addition of TEA. The mixture was stirred for 10 minutes at room temperature. Once the solution was homogeneous, PHOST stock solution #3 was added and stirred for 10 minutes at room temperature. Next, silica nanoparticle stock solution #4 was added. The resulting final NQ ink was mechanically stirred for 1 hour at room temperature then filtered through a 0.22 m polypropylene filter.

Inventive NQ ink 2 was also prepared according to the procedure described below. Generally, a solution of S-poly(3-MEET) amine adduct, TEA, and SiO₂ nanoparticles and another solution of TFE-VEFS 1 were prepared. These two solutions were combined to give NQ ink 2.

The solution of S-poly(3-MEET) amine adduct, TEA, and SiO₂ nanoparticles was prepared as follows.

S-poly(3-MEET) amine adduct was prepared by combining an aqueous dispersion of S-poly(3-MEET) with an excess of triethylamine, followed by drying by spray-drying. It is believed that the mass of S-poly(3-MEET) in the adduct is 77.7%, while the remaining 22.3% by mass is triethylamine. The product was isolated as black powder and was stored in the glovebox under nitrogen.

In a suitable container, ethylene glycol was combined with a solution of ˜0.57% triethylamine in ethylene glycol, where the total amount of triethylamine in the resulting mixture, including the TEA believed to be in the above amine adduct, adds up to ˜0.95% triethylamine in the final ink. Next, a sufficient amount of 20-21 wt % silica dispersion in ethylene glycol was added to give 4.35% of silica (by mass of ink). This mixture is then stirred on a hotplate at ˜500 rpm and warmed with the hotplate set at 90° C.

Once warm, a sufficient amount of the previously-prepared S-poly(3-MEET) amine adduct was added while stirring on the hotplate to give 0.45% of conductive polymer by mass of ink. This solution is then allowed to continue stirring at temperature overnight.

The solution of TFE-VEFS 1 was prepared as follows.

Rotary evaporation was used to isolate the solid component of an aqueous dispersion of TFE-VEFS 1 copolymer and was stored in the glovebox under nitrogen.

In a suitable container, ethylene glycol was stirred at 500 rpm and warmed with a hotplate set at 90° C. Once the solvent is warmed, a sufficient amount of dried TFE-VEFS 1 copolymer that is stored in the glovebox to create a 2% solution in ethylene glycol was weighed and then added to the solvent while it is still stirring on the hotplate. This solution is then allowed to continue stirring overnight.

The inventive NQ ink 2 was then prepared by adding the appropriate amount of TFE-VEFS 1 copolymer solution to the previously-prepared solution of S-poly(3-MEET) amine adduct, TEA, and SiO₂ nanoparticles while warm. The ink is then allowed to stir at ˜500 rpm for 1-2 hours at 90° C. After stirring, the ink was then allowed to stir at room temperature until cool. Once cooled, the ink is filtered under pressure, and then passed through 0.22 m filters.

A comparative ink, designated Comparative NQ ink, was also prepared for comparison.

The compositions of NQ inks 1 and 2, and Comparative NQ ink are summarized in Table 2 below.

TABLE 2
Inventive NQ inks 1 and 2, and Comparative NQ ink

| | NQ ink 1 | NQ ink 2 | Comparative NQ ink |
|---|---|---|---|
| Component | wt % | wt % | wt % |
| S-poly(3-MEET) | 0.15 (solids) | 0.45 (solids) | 0.40 (solids) |
| TFE-VEFS 1 | 0.10 (solids) | 0.20 (solids) | 0.27 (solids) |
| PHOST | 1.625 (solids) | — | 6.03 (solids) |
| Silica | 0.625 | 4.35 | — |
| nanoparticles | | | |
| TEA | 1.00 | 0.95 | 0.90 |
| EG | 2.50 | 94.05 | — |
| DMSO | 90.2 | — | 92.40 |

### Example 2. OLED Device Fabrication and Characterization

HILs were prepared from the inventive NQ inks and screened in OLED devices. HILs were also prepared from the Comparative NQ ink, which is free of nanoparticles, as comparative HIL films.

The device fabrication described below is intended as an example and does not in any way imply the limitation of the invention to the said fabrication process, device architecture (sequence, number of layers, etc.) or materials other than the HIL materials claimed.

The OLED devices described herein were fabricated on indium tin oxide (ITO) surfaces deposited on glass substrates.

The ITO surface was pre-patterned to define the pixel area of 0.09 cm². Before depositing an NQ ink to form an HIL on the substrates, pre-conditioning of the substrates was performed. The device substrates were first cleaned by ultrasonication in various solutions or solvents. The device substrates were ultrasonicated in a dilute soap solution, followed by distilled water, then acetone, and then isopropanol, each for about 20 minutes. The substrates were dried under nitrogen flow. Subsequently, the device substrates were then transferred to a vacuum oven set at 120° C. and kept under partial vacuum (with nitrogen purging) until ready for use. The device substrates were treated in a UV-Ozone chamber operating at 300 W for 20 minutes immediately prior to use.

Before the HIL ink composition is deposited onto an ITO surface, filtering of the ink composition through a polypropylene 0.2-μm filter was performed.

The HIL was formed on the device substrate by spin coating the NQ ink in air. Generally, the thickness of the HIL after spin-coating onto the ITO-patterned substrates is determined by several parameters such as spin speed, spin time, substrate size, quality of the substrate surface, and the design of the spin-coater. General rules for obtaining certain layer thickness are known to those of ordinary skill in the art. After spin-coating, the HIL layer was allowed to briefly set (about 5 minutes) in air under heating. The HIL layer was then dried on a hot plate under inert atmosphere, typically at a temperature (anneal temperature) of from 150° C. to 250° C. for 15-30 minutes. The substrates comprising the HIL layers prepared were stored in the dark under partial vacuum before use.

The substrates comprising the inventive HIL layers were then transferred to a vacuum chamber where the remaining layers of the device stack were deposited by means of physical vapor deposition.

All steps in the coating and drying process are done under an inert atmosphere, unless otherwise stated.

N,N′-bis(1-naphtalenyl)-N,N′-bis(phenyl)benzidine (NPB) was deposited as a hole transport layer on top of the HIL followed by an emissive layer, a tris(8-hydroxyquinolinato)aluminum (ALQ3) electron transport and emissive layer, and LiF and Al as cathode. The pre-patterned ITO on glass acts as the anode.

The OLED device comprises pixels on a glass substrate whose electrodes extended outside the encapsulated area of the device which contain the light emitting portion of the pixels. The typical area of each pixel is 0.09 cm². The electrodes were contacted with a current source meter such as a Keithley 2400 source meter with a bias applied to the aluminum electrode while the ITO electrode was earthed. This results in positively charged carriers (holes) and negatively charged carriers being injected into the device which form excitons and generate light. In this example, the HIL assists the injection of charge carriers into the light emitting layer.

Simultaneously, another Keithley 2400 source meter is used to address a large area silicon photodiode. This photodiode is maintained at zero volts bias by the 2400 source meter. It is placed in direct contact with area of the glass substrate directly below the lighted area of the OLED pixel. The photodiode collects the light generated by the OLED converting them into photocurrent which is in turn read by the source meter. The photodiode current generated is quantified into optical units (candelas/sq. meter) by calibrating it with the help of a Minolta CS-200 Chromameter.

During the testing of the device, the Keithley 2400 addressing the OLED pixel applies a voltage sweep to it. The resultant current passing through the pixel is measured. At the same time the current passing through the OLED pixel results in light being generated which then results in a photocurrent reading by the other Keithley 2400 connected to the photodiode. Thus the voltage-current-light or IVL data for the pixel is generated.

Green OLEDs having HILs made from NQ ink 1 and Comparative NQ ink were made.

In addition, blue OLEDs having HILs made from NQ ink 2 and a comparative aqueous (AQ) ink comprising S-poly(3-MEET) and an aqueous solvent (water/butyl cellusolve), which is designated Comparative AQ ink, were made.

The percentages of SiO₂ nanoparticles in the HILs of the OLEDs made are shown in Table 3 below.

TABLE 3
SiO₂ nanoparticles in the HILs made from inventive NQ ink 1,
NQ ink 2, Comparative NQ, and Comparative AQ ink

| | | | Comparative | Comparative |
|---|---|---|---|---|
| | NQ ink 1 | NQ ink 2 | NQ ink | AQ ink |
| Silica | 25 | 87 | 0 | 0 |
| nanoparticles | | | | |
| (%) | | | | |

### Example 3. Green OLED Device Properties

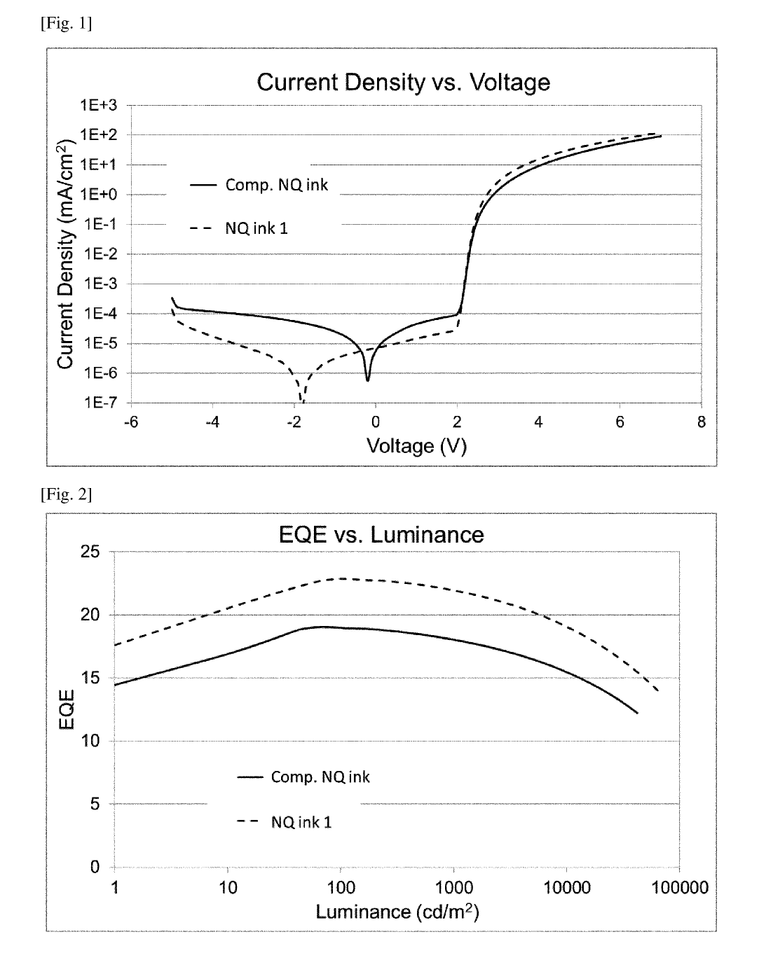

The current density vs. voltage characteristics of the green OLED having HIL made from NQ ink 1 and the green OLED having HIL made from Comparative NQ ink were determined and compared. FIG. 1 shows the current density as a function of voltage for the green OLED having HIL made from NQ ink 1 and the green OLED having HIL made from Comparative NQ ink.

The inventive HIL increases electrical resistivity to reduce the leakage current and cross-talk between pixels.

The performance of the green OLED having HIL made from NQ ink 1 and the green OLED having HIL made from Comparative NQ ink were determined at normal (0°) incident angle. The performance of the greens OLEDs is summarized in Table 4 below.

TABLE 4
Performance of green OLEDs

| | | 1 kcd/m² | | | 10 mA/cm² | | 5 kcd/m² |
|---|---|---|---|---|---|---|---|
| HIL | SiO₂ (%) | V | Cd/A | % EQE | CIEx | CIEy | LT(97) |
| Comparative | 0 | 3.0 | 61.1 | 17.5 | 0.351 | 0.616 | 525 |
| NQ ink | | | | | | | |
| NQ ink 1 | 25 | 2.8 | 76.0 | 21.8 | 0.319 | 0.640 | 580 |

As reported in Table 4, the CIE x coordinate decreased from 0.351 to 0.319 and the CIE y coordinate increased from 0.616 to 0.640 in the device made from NQ ink 1, which contains SiO₂ nanoparticles, compared to the device made from Comparative NQ ink, which does not contain SiO2 nanoparticles. It would be understood by the ordinarily-skilled artisan that the combination of the CIE x coordinate decrease and the CIE y coordinate increase corresponds to a shift towards green light having a wavelength of 520 nm, which is indicative of improved color saturation for a green OLED.

FIG. 2 shows the % EQE as a function of luminance for the green OLED having HIL made from NQ ink 1 and the green OLED having HIL made from Comparative NQ ink. The use of SiO₂ in the green OLED having HIL made from NQ ink 1 resulted in improvement in luminance efficiency by 18% when compared to the OLED having HIL made from Comparative NQ ink, which does not have SiO₂ nanoparticles. Without wishing to be bound by theory, the increase in efficiency is believed to be due to increased internal light outcoupling resulting from the addition of SiO₂ nanoparticles.

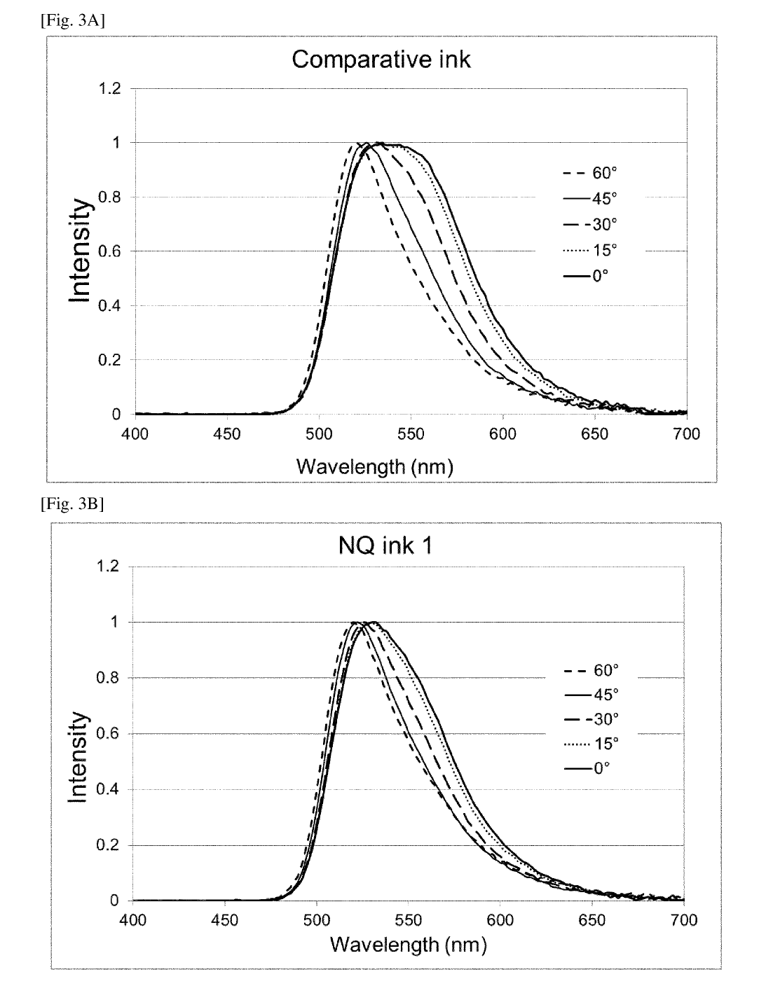

The electroluminescence (EL) spectra of each green OLED were determined at various incident angles (0°, 15°, 30°, 45°, and 60°). FIG. 3A shows the electroluminescence spectra of the green OLED having HIL made from Comparative NQ ink determined at various incident angles. FIG. 3B shows the electroluminescence spectra of the green OLED having HIL made from NQ ink 1 determined at various incident angles. Comparison of the spectra shown in FIGS. 3A and 3B shows improved color stability in the inventive HIL when compared to the comparative HIL as evidenced by smaller changes in EL spectrum in the inventive HIL.

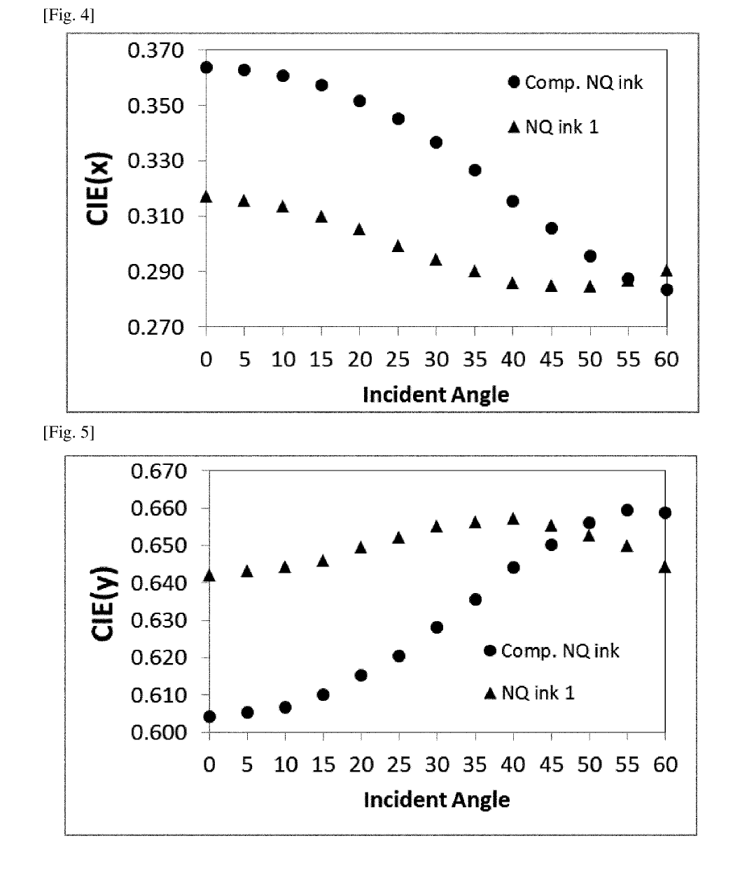

The CIE x and y coordinates of each green OLED were determined as a function of incident angle. FIG. 4 shows the CIE x coordinates of the green OLED having HIL made from Comparative NQ ink and the CIE x coordinates of the green OLED having HIL made from inventive ink 1 as a function of incident angle. Similarly, FIG. 5 shows the CIE y coordinates of the green OLED having HIL made from Comparative NQ ink and the CIE y coordinates of the green OLED having HIL made from inventive ink 1 as a function of incident angle. The plots in FIGS. 4 and 5 show improved color stability in the inventive HIL when compared to the comparative HIL as evidenced by smaller changes (flatter curve) in CIE x and y coordinates with varying incident angle.

### Example 4. Blue OLED Device Properties

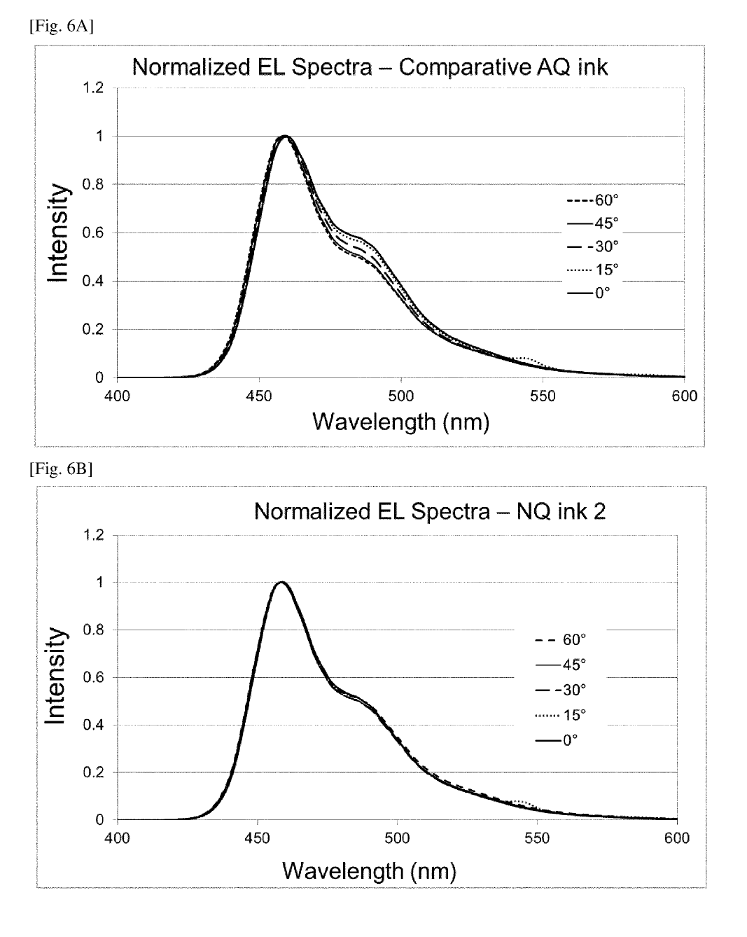

The EL spectra of the blue OLED having an HIL made from NQ ink 2 and the blue OLED having an HIL made from Comparative AQ ink were determined at various incident angles (0°, 15°, 30°, 45°, and 60°). FIG. 6A shows the EL spectra of the blue OLED having HIL made from Comparative AQ inkdetermined at various incident angles. FIG. 6B shows the EL spectra of the blue OLED having HIL made from NQ ink 2 determined at various incident angles. Comparison of the spectra shown in FIGS. 6A and 6B shows improved color stability in the inventive HIL when compared to the comparative HIL as evidenced by smaller changes in EL spectrum in the inventive HIL.

FIG. 7 shows a radial plot of brightness vs. incident angle of the blue OLED having an HIL made from NQ ink 2 and the blue OLED having an HIL made from Comparative AQ ink. As can be seen in FIG. 7, the inventive HIL exhibits very little deviation in brightness with incident angle when compared to that of comparative HIL.

### Example 5. Refractive Index

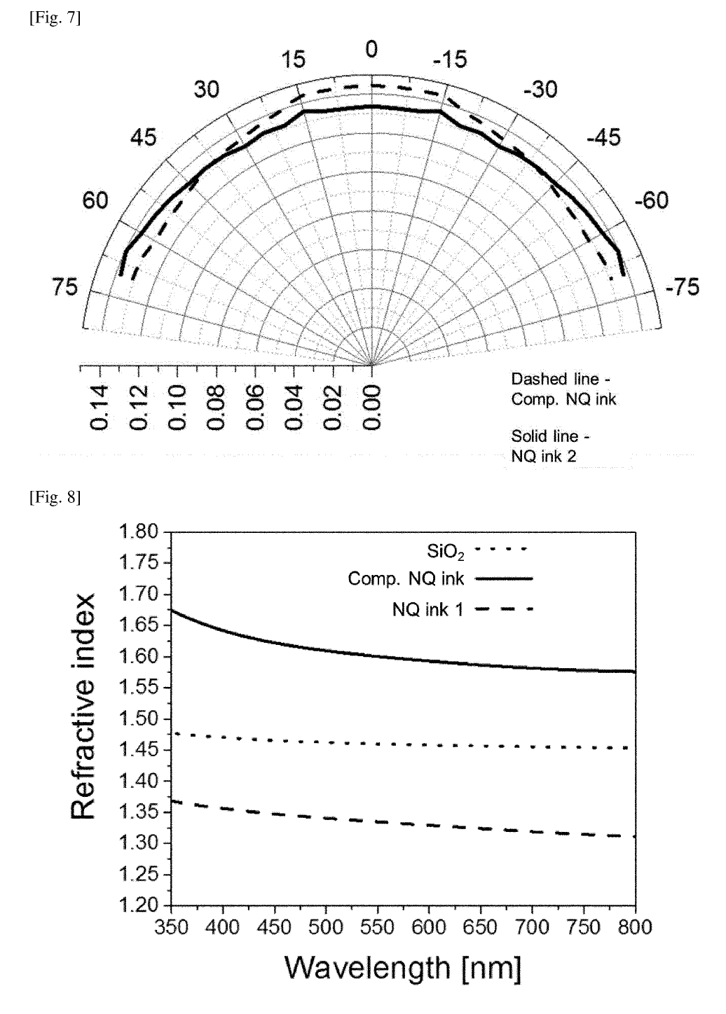

FIG. 8 shows a comparison of the refractive index of an HIL prepared from NQ ink 1, an HIL prepared from Comparative NQ ink, and the refractive index of SiO₂ versus wavelength. The refractive index shown in FIG. 8 was obtained from a literature source (Edward D. Palik, Handbook of Optical Constants of Solids, Vol. 1 (Academic Press 1985)).

As shown in FIG. 8, the refractive index of the HIL prepared from NQ ink 1 is lower than both that of HIL prepared from Comparative NQ ink and that of SiO₂ alone.

The components used in the following Example 6 to 9 are summarized in the following Table 5.

TABLE 5
Summary of components used in Examples 6 to 9

| | |
|---|---|
| S-poly(3- | Sulfonated poly(3-MEET) |
| MEET) | |
| TFE-VEFS 1 | TFE/perfluoro-2-(vinyloxy)ethane-1-sulfonic acid |
| | copolymer having equivalent weight of 676 g |
| | polymer/mol acid (available from Solvay as AQUIVION ® |
| | D66-20BS); n:m = 8:2 |
| TEA | Triethylamine |
| EG-ST | 20-21 wt % silica dispersion in ethylene glycol |
| | (ORGANOSILICASOL ™ EG-ST, available from Nissan |
| | Chemical) |
| EG | Ethylene glycol |
| DEG | Diethylene glycol |
| EGMPE | Ethylene glycol monopropyl ether |
| PCN | 3-methoxypropionitrile |

[1] Preparation of a Charge-Transporting Varnish

### Example 6

First, an aqueous solution D66-20BS was evaporated using an evaporator, and the resultant residue was dried at 80° C. for 1 hour under reduced pressure using a vacuum drier, to therby obtain a powder of D66-20BS. Using the obtained powder, a solution of D66-20BS in ethylene glycol having a concentration of 2 wt % was prepared. This solution was prepared by stirring at 90° C. for 1 hour at 400 rpm using a hot stirrer.

Then, another vessel was provided and, in this vessel, 5.55 g of S-poly(3-MEET), a charge-transporting material, was dispersed in a mixture of 92.45 g of ethylene glycol (manufactured and sold by KANTO CHEMICAL CO., INC.) and 2.28 g of triethylamine (manufactured and sold by Tokyo Chemical Industry Co., Ltd.). This solution was prepared by stirring at 90° C. for 1 hour using a hot stirrer. Then, 96 g of the 2 wt % solution of D66-20BS in ethylene glycol was added, and the resultant mixture was stirred at 90° C. for 1 hour at 400 rpm using a hot stirrer. Finally, 203.71 g of EG-ST was added, and the resultant mixture was stirred at 90° C. for 10 minutes at 400 rpm using a hot stirrer. The resultant solution was filtered with a PP syringe filter (pore size: 0.2 m), to thereby obtain a charge-transporting varnish having a concentration of 12 wt %.

### Example 7

25 g of the charge-transporting varnish (12 wt %) obtained in Example 6 was diluted with a solution prepared from ethylene glycol and triethylamine (99:1, weight ratio) in another vessel, to thereby obtain a charge-transporting varnish having a concentration of 3 wt %. This solution was prepared by stirring at 70° C. for 1 hour at 400 rpm using a hot stirrer.

### Example 8

First, an aqueous solution D66-20BS was evaporated using an evaporator, and the resultant residue was dried at 80° C. for 1 hour under reduced pressure using a vacuum drier, to therby obtain a powder of D66-20BS. Using the obtained powder, a solution of D66-20BS in 3-methoxypropionitrile having a concentration of 1 wt % was prepared. This solution was prepared by stirring at 70° C. for 15 minutes at 400 rpm using a hot stirrer.

Then, another vessel was provided and, in this vessel, 0.069 g of S-poly(3-MEET), a charge-transporting material, was dispersed in a mixture of 2.426 of 3-methoxypropionitrile (manufactured and sold by Tokyo Chemical Industry Co., Ltd.), 7.603 g of diethylene glycol (manufactured and sold by KANTO CHEMICAL CO., INC.) and 0.179 g of triethylamine (manufactured and sold by Tokyo Chemical Industry Co., Ltd.). This solution was prepared by stirring at 70° C. for 1.5 hours at 400 rpm using a hot stirrer. Then, 4.802 g of ethylene glycol monopropyl ether (manufactured and sold by Tokyo Chemical Industry Co., Ltd.) was added, and the resultant mixture was stirred at 70° C. for 10 minutes at 400 rpm using a hot stirrer. Further, 2.522 g of EG-ST was added, and the resultant mixture was stirred at 70° C. for 10 minutes at 400 rpm. Finally, 2.400 g of the 1 wt % solution of D66-20BS in 3-methoxypropionitrile was added, and the resultant mixture was stirred at 70° C. for 1 hour at 400 rpm. The resultant solution was filtered with a syringe filter (pore size: 0.2 m), to thereby obtain a charge-transporting varnish having a concentration of 3 wt %.

[2] Production of Organic EL Devices and Evaluation of their Properties

### Example 9

The varnish obtained in each of Examples 7 and 8 was applied on an ITO substrate using a spin coater, and the substrate was dried at 80° C. for 1 minute under air atmosphere. Then, the dried ITO substrate was inserted into a glove box and calcined under nitrogen atmosphere at 230° C. for 30 minutes, to thereby form, on the ITO substrate, a film having a thickness of 50 nm. As the ITO substrate, a glass substrate (25 mm×25 mm×0.7 t) with a patterned film of indium tin oxide (ITO) (having a film thickness of 150 nm) formed on the surface of the substrate was used. Before use, impurities on the surface of this substrate was removed by an O₂ plasma cleaning apparatus (150 W, 30 seconds).

Next, the ITO substrate having formed thereon the film was subjected to a process to form a film of α-NPD (N,N′-di(1-naphthyl)-N,N′-diphenylbenzidine) at the film forming rate of 0.2 nm/second using a vapor deposition apparatus (under the degree of vacuum of 1.0×10⁵ Pa), until the resultant film had a thickness of 30 nm. Then, another film of HTEB-01 (an electron blocking material manufactured and sold by Tokyo Chemical Industry Co., Ltd.) having a thickness of 10 nm was formed. Further, this substrate was subjected to a process of co-vapor deposition of NS60 (a host material of a light emmiting layer manufactured and sold by NIPPON STEEL & SUMIKIN CHEMICAL CO., LTD.) and Ir(PPy)₃ (a dopant material of a light emmiting layer). The co-vapor deposition process was conducted until the film having a thickness of 40 nm was laminated, under the control of the deposition rate so that the concentration of Ir(PPy)₃ was 6%. Then a film of each of Alq₃, lithium fluoride and aluminum was sequentially laminated, to thereby obtain an organic EL device. Each of Alq₃ and aluminum was deposited at the deposition rate of 0.2 nm/second, and lithium fluoride was deposited at the deposition rate of 0.02 nm/second. The film thickness of each of Alq₃, aluminum and lithium fluoride was 20 nm, 0.5 nm and 80 nm, respectively.

The properties of the organic EL device were evaluated after the device was sealed with sealing substrates, in order to prevent deterioration of properties by the influence of oxygen, water and like in air. The sealing was conducted as follows. Under nitrogen atmosphere with an oxygen concentration of 2 ppm or less and dew point of −76° C. or less, the organic EL device was put into the space between sealing substrates and the sealing substrates were adhered to each other with an adhesive (MORESCO Moisture Cut WB90US(P) manufactured and sold by MORESCO Corporation). In this process, a water-trapping agent (HD-071010W-40 manufactured and sold by DYNIC CORPORATION) was put into the space between sealing substrates, together with the organic EL device. The adhered sealing substrates were irradiated with UV light (wavelength: 365 nm, irradiance level: 6,000 mJ/cm²) and annealed at 80° C. for 1 hour to harden the adhesive.

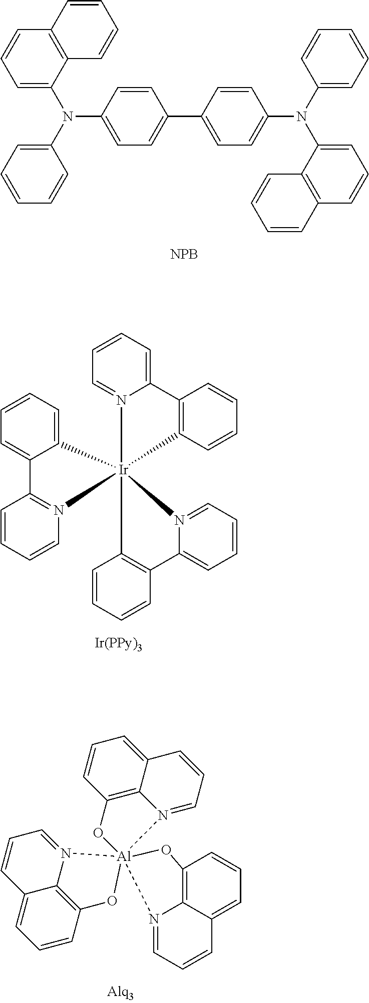

With respect to the device of each of Examples 7 and 8 driven at the initial luminance of 5000 cd/m², the drive voltage, current density, luminance efficiency and half-life of the luminance (the time of period required for the luminance to become half of the initial luminance 5000 cd/m²) were determined. The results are given in Table 6 below.

TABLE 6

| | Drive | Current | Current | Half-life of |
|---|---|---|---|---|
| Example | voltage | density | efficiency | the luminance |
| No. | (V) | (mA/cm³) | (cd/A) | (hours) |
| 7 | 5.6 | 9.3 | 53.8 | 1496.6 |
| 8 | 5.5 | 8.7 | 57.5 | 1568.9 |

As shown in Table 6, in an organic EL device equipped with the charge-transporting film of the present invention produced only with revised composition of solvents, the drive voltage was lowered and the current efficiency was improved. Further, the device exhibited excellent life properties.

This application claims priority to United States Provisional Application No. U.S. 62/271,743 filed on Dec. 28, 2015, the entire contents of which are incorporated by reference herein.

1. A device comprising a hole-carrying film, the hole-carrying film comprising:
(a) a polythiophene comprising a repeating unit complying with formula (I) 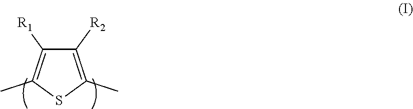
wherein R₁ and R₂ are each, independently, H, alkyl, fluoroalkyl, alkoxy, aryloxy, or —O—[Z—O]ₚ—Rₑ;
wherein
Z is an optionally halogenated hydrocarbylene group,
p is equal to or greater than 1, and
Rₑ is H, alkyl, fluoroalkyl, or aryl; and
(b) one or more nanoparticles,
wherein the one or more nanoparticles are metallic or metalloid nanoparticles.

2. (canceled)

3. The device according to claim 1, wherein R₁ is H and R₂ is other than H, or wherein R₁ and R₂ are both other than H.

4.-7. (canceled)

8. The device according to claim 1, wherein the polythiophene comprises a repeating unit selected from the group consisting of 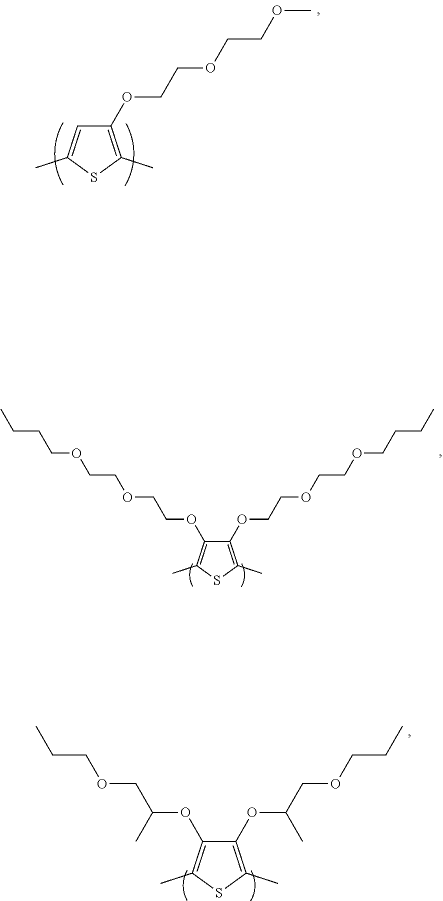
and combinations thereof.

9. The device according to claim 1, wherein the polythiophene is sulfonated.

10. The device according to claim 9, wherein the polythiophene is a sulfonated poly(3-MEET).

11. The device according to claim 1, wherein the polythiophene comprises repeating units complying with formula (I) in an amount of greater than 50% by weight, based on the total weight of the repeating units.

12. The device according to claim 1, wherein one or more nanoparticles are metalloid nanoparticles.

13. The device according to claim 12, wherein the metalloid nanoparticles comprise B₂O₃, B₂O, SiO₂, SiO, GeO₂, GeO, As₂O₄, As₂O₃, As₂O₅, Sb₂O₃, TeO₂, SnO₂, SnO, or mixtures thereof.

14. (canceled)

15. The device according to claim 1, wherein the one or more nanoparticles comprise one or more organic capping groups.

16. (canceled)

17. The device according to claim 1, wherein the hole-carrying film further comprises a synthetic polymer comprising one or more acidic groups.

18.-22. (canceled)

23. The device according to claim 1, wherein the hole-carrying film further comprises one or more amine compounds.

24. The device according to claim 1 wherein the device is an OLED, OPV, transistor, capacitor, sensor, transducer, drug release device, electrochromic device, or battery device.

25.-49. (canceled)

50. A non-aqueous ink composition comprising:
(a) a sulfonated polythiophene, being a sulfonated product of a polythiophene,
the polythiophene comprising a repeating unit complying with formula (I): 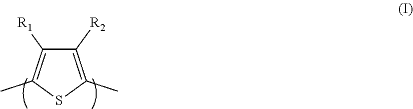
wherein R₁ and R₂ are each, independently, H, alkyl, fluoroalkyl, alkoxy, aryloxy, or —O—[Z—O]ₚ—Rₑ;
wherein
Z is an optionally halogenated hydrocarbylene group,
p is equal to or greater than 1, and
Rₑ is H, alkyl, fluoroalkyl, or aryl;
(b) one or more amine compounds;
(c) one or more metalloid nanoparticles;
(d) optionally a synthetic polymer comprising one or more acidic groups; and
(e) a liquid carrier which is 1) or 2) below:
1) a liquid carrier consisting of (A) one or more glycol-based solvents, and
2) a liquid carrier comprising (A) one or more glycol-based solvents and (B) one or more organic solvents other than the glycol-based solvents.

51.-52. (canceled)

53. The non-aqueous ink composition according to claim 50 wherein the organic solvent (B) is a nitrile, alcohol, aromatic ether or aromatic hydrocarbon.

54. The non-aqueous ink composition according to claim 50 wherein the proportion by weight (wtA) of the glycol-based solvent (A) and the proportion by weight (wtB) of the organic solvent (B) satisfy the relationship represented by the following formula (1-1):
0.05≤wtB/(wtA+wtB)≤0.50 (1-1).

55.-60. (canceled)

61. The non-aqueous ink composition according to claim 50, wherein the polythiophene comprises a repeating unit selected from the group consisting of 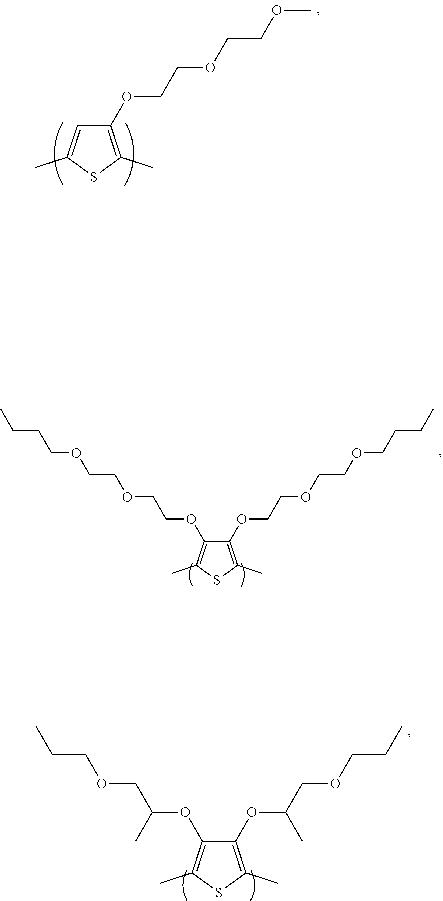
and combinations thereof.

62. The non-aqueous ink composition according to claim 50, wherein the sulfonated polythiophene is sulfonated poly(3-MEET).

63. The non-aqueous ink composition according to claim 50, wherein the amine compound is a tertiary alkylamine compound.

64. (canceled)

65. The non-aqueous ink composition according to claim 50, wherein the metalloid nanoparticles comprise B₂O₃, B₂O, SiO₂, SiO, GeO₂, GeO, As₂O₄, As₂O₃, As₂O₅, Sb₂O₃, TeO₂, SnO₂, SnO, or mixtures thereof.

66.-69. (canceled)

70. The device according to claim 12, wherein the hole-carrying film further comprises
(c) one or more amine compounds, and
(d) optionally a synthetic polymer comprising one or more acidic groups.
